(19) United States
(12) Patent Application Publication
(10) Pub. No.: US 2024/0381762 A1
(43) Pub. Date: Nov. 14, 2024

(54) RESIN, RESIN COMPOSITION AND DISPLAY DEVICE USING THE SAME

(71) Applicant: DUK SAN NEOLUX CO., LTD, Cheonan-si (KR)

(72) Inventors: Changmin LEE, Cheonan-si (KR); Hanwook SEO, Cheonan-si (KR); Kyung Soo KIM, Cheonan-si (KR); Yeon Soo LEE, Cheonan-si (KR); Jun BAE, Cheonan-si (KR); Jun Ki KIM, Cheonan-si (KR); Hyunsang CHO, Cheonan-si (KR); Jaehyun LIM, Cheonan-si (KR); Seo Jeong JEON, Cheonan-si (KR); Soung Yun MUN, Cheonan-si (KR)

(73) Assignee: DUK SAN NEOLUX CO., LTD, Cheonan-si (KR)

(21) Appl. No.: 18/658,162

(22) Filed: May 8, 2024

(30) Foreign Application Priority Data
May 8, 2023 (KR) 10-2023-0059431

(51) Int. Cl. H10K 85/60; C09K 11/02; C09K 11/07

(52) U.S. Cl. CPC H10K 85/631; C09K 11/025; C09K 11/07; C09K 2211/1007; C09K 2211/1014

(57) ABSTRACT

According to an embodiment of the present disclosure, a display panel can be provided using a dye, which has excellent light resistance that is not deformed by external sunlight and excellent chemical resistance that does not change color by other solvents during the process even when molded at low temperatures, and a photoinitiator, which has a radical-forming functional group having a weak bond, and thus the display panel can be decomposed at lower temperatures, and the pattern thus formed not only emits a smaller amount of outgas, but also is formed with a higher sensitivity, thus having more improved reliability.

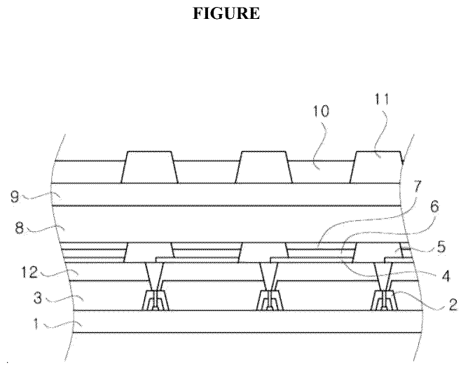

### TECHNICAL FIELD

The present disclosure relates to a photosensitive resin composition and a display device capable of realizing a clearer image using the same.

### BACKGROUND

A liquid crystal display device (LCD), an organic light emitting display device (OLED), etc. are widely used in flat panel displays. Among them, the organic light emitting display device in particular has advantages such as low power consumption, fast response speed, high color reproducibility, high luminance, and a wide viewing angle.

In the case of the organic light emitting display device, a polarizing film is used to block the light reflected from the panel due to incident external light, and there is a disadvantage in that the polarizing film is not suitable for application to a flexible device due to a lack of a bending property.

As a method for solving the above problem, a method of forming an inorganic film for blocking light on an upper substrate as well as a color filter and a black matrix, etc. have been proposed. However, the method has a limit in obtaining a desired level of anti-reflection effect, and does not specifically suggest a method for replacing the polarizing film.

Meanwhile, the coloring pattern is used as red, green, and blue color filters in a liquid crystal display device, not only in a liquid crystal display but also in an organic light emitting display.

In preparing the coloring pattern, carbon black and inorganic pigments as well as various kinds of organic pigments are used as colorants, and the pigment dispersion in which these are dispersed is mixed with other compositions to form a pattern.

The organic light emitting display made in the pixel formed in this way can realize more vivid colors. However, the coloring pattern has a large amount of outgas, and this outgas reduces the lifetime of the display.

### SUMMARY

In order to solve the problems of the prior art, an embodiment of the present disclosure is to provide a pixel with high reliability as well as a vivid color by implementing a colored pattern with a low amount of outgas on an electrode substrate by way of using a dye, which has excellent light resistance that is not deformed by external sunlight and excellent chemical resistance that does not change color by other solvents during the process even when molded at low temperatures, and a photoinitiator, which has a radical-forming functional group having a weak bond.

The present disclosure provides a photosensitive resin composition including an alkali-soluble resin; a reactive unsaturated compound; a photoinitiator having a maximum molar absorption coefficient of 10,000 (L/mol·cm) or more in the region of 320 nm to 380 nm and a loss of 5 wt % at 200° C. or less; a reactive dye including a chromophore of Formula (4) below and a protecting group of Formula (5) below; and a solvent.

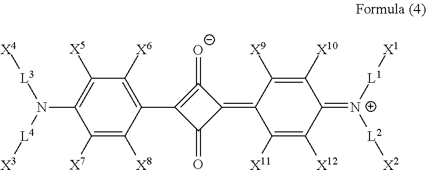

In Formula 4 above,
1) L¹ to L⁴ are each independently a single bond; a fluorenylene group; C₁₋₃₀ alkylene; a C₃₋₃₀ cycloalkylene group; a C₁₋₃₀ alkoxylene group, a C₂₋₃₀ polyethyleneoxy group; a C₆₋₃₀ arylene group; a C₂₋₃₀ heterocyclic ring; or a combination thereof,
2) X¹ to X⁴ are each independently hydrogen; deuterium; a fluorenyl group; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₃₀ alkyl group; a C₂₋₃₀ alkenyl group; a C₂₋₃₀ alkynyl group; a C₁₋₃₀ alkoxy group; a C₆₋₃₀ aryloxy group; a C₃₋₃₀ cycloalkyl group; Formula (4-A); or a combination thereof,
3) at least one of X¹ to X⁴ is Formula (4-A),

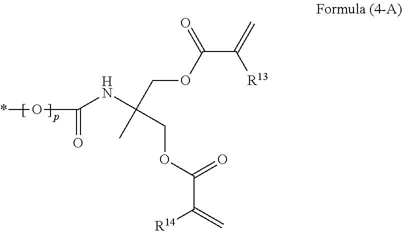

wherein in Formula (4-A) above,
3-1) * is a moiety bonded to L¹ to L⁴ or N,
3-2) p is an integer from 0 to 1,
3-3) when Formula (4-A) is directly bonded to N, p is 0, and
3-4) R¹³ and R¹⁴ are independently hydrogen or a methyl group,
4) X⁵ to X¹² are each independently hydrogen; deuterium; halogen; a fluorenyl group; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₃₀ alkyl group; a C₂₋₃₀ alkenyl group; a C₂₋₃₀ alkynyl group; a C₁₋₃₀ alkoxy group; a C₆₋₃₀ aryloxy group; a C₃₋₃₀ cycloalkyl group; or a C₁₋₃₀ alkylamine group,
5) X⁵ to X¹² may bind to each other to form a ring,

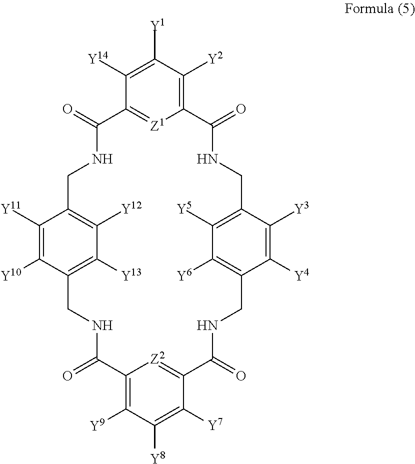

wherein in Formula (5) above,
6) Z¹ and Z² are each independently a carbon atom or a nitrogen atom,
7) Y¹ to Y¹⁴ are each independently hydrogen; deuterium; halogen; a fluorenyl group; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₃₀ alkyl group; a C₂₋₃₀ alkenyl group; a C₂₋₃₀ alkynyl group; a C₁₋₃₀ alkoxy group; a C₆₋₃₀ aryloxy group; a C₃₋₃₀ cycloalkyl group; or a C₁₋₃₀ alkylamine group,
8) Y¹ to Y¹⁴ may bind to each other to form a ring,
9) the X¹ to X¹⁴, Y¹ to Y¹⁴, and L¹ to L⁴ may each be further substituted with one or more substituents selected from the group consisting of deuterium; halogen; a silane group substituted or unsubstituted with a C₁₋₃₀ alkyl group or C₆₋₃₀ aryl group; a siloxane group; a boron group; a germanium group; a cyano group; an amino group; a nitro group; a C₁₋₃₀ alkylthio group; a C₁₋₃₀ alkoxy group; a C₆₋₃₀ arylalkoxy group; a C₁₋₃₀ alkyl group; a C₂₋₃₀ alkenyl group; a C₂₋₃₀ alkynyl group; a C₆₋₃₀ aryl group; a C₆₋₃₀ aryl group substituted with deuterium; a fluorenyl group; a C₂₋₃₀ heterocyclic group including at least one heteroatom among O, N, S, Si, and P; a C₃₋₃₀ alicyclic group; a C₇₋₃₀ arylalkyl group; a C₈₋₃₀ arylalkenyl group; and a combination thereof; or may form a ring between the neighboring substituents.

Preferably, the alkali-soluble resin includes a repeating unit represented by Formula (1) below.

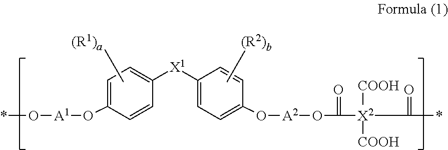

In still another specific embodiment, the present disclosure provides a pattern or film formed of the photosensitive resin composition.

In still another specific embodiment, the present disclosure provides an organic light emitting display device including the pattern or film.

In still another specific embodiment, the present disclosure provides an electronic device including the display device and a control unit for operating the display device.

### Advantageous Effects

The resin composition according to an embodiment of the present disclosure can provide a display panel can be provided using a dye, which has excellent light resistance that is not deformed by external sunlight and excellent chemical resistance that does not change color by other solvents during the process even when molded at low temperatures, and a photoinitiator, which has a radical-forming functional group having a weak bond, and thus the display panel can be decomposed at lower temperatures, and the pattern thus formed not only emits a smaller amount of outgas, but also is formed with a higher sensitivity, thus having more improved reliability.

### BRIEF DESCRIPTION OF THE DRAWINGS

The FIGURE schematically illustrates a display device according to an embodiment of the present disclosure.

### MODE FOR CARRYING OUT THE INVENTION

Hereinafter, some embodiments of the present disclosure will be described in detail with reference to exemplary drawings. In adding reference numerals to components of each drawing, the same components may have the same reference numerals even though they are indicated in different drawings.

When it is determined that a detailed description of a related known constitution or function may obscure the gist of the present disclosure in describing the present disclosure, the detailed description thereof may be omitted. When the expressions “includes”, “has”, “consisting of”, etc. mentioned in this specification are used, other parts may be added unless “only” is used. When a component is expressed in the singular form, it may include a case in which the plural form is included unless otherwise explicitly stated.

Additionally, in describing the components of the present disclosure, terms such as first, second, A, B, (a), (b), etc. may be used. These terms are only for distinguishing the components from other components, and the essence, order, sequence, the number, etc. of the components are not limited by the terms.

In the description of the positional relationship of the components, when two or more components are described as being “connected”, “linked”, or “fused”, etc., the two or more components may be directly “connected”, “linked”, or “fused”, but it should be understood that the two or more components may also be “connected”, “linked”, or “fused” by way of a further “interposition” of a different component. In particular, the different component may be included in any one or more of the two or more components that are to be “connected”, “linked”, or “fused” to each other.

Additionally, when a component (e.g., a layer, a film, a region, a plate, etc.) is described to be “on top” or “on” of another component, it should be understood that this may also include a case where another component is “immediately on top of” as well as a case where another component is disposed therebetween. In contrast, it should be understood that when a component is described to be “immediately on top of” another component, it should be understood that there is no other component disposed therebetween.

In the description of the temporal flow relationship relating to the components, the operation method, or the preparation method, for example, when the temporal precedence or flow precedence is described by way of “after”, “subsequently”, “thereafter”, “before”, etc., it may also include cases where the flow is not continuous unless terms such as “immediately” or “directly” are used.

Meanwhile, when the reference is made to numerical values or corresponding information for components, numerical values or corresponding information may be interpreted as including an error range that may occur due to various factors (e.g., procedural factors, internal or external shocks, noise, etc.) even if it is it not explicitly stated.

The terms used in this specification and the appended claims are as follows, unless otherwise stated, without departing from the spirit of the present disclosure.

As used herein, the term “halo” or “halogen” includes fluorine (F), chlorine (Cl), bromine (Br), and iodine (I), unless otherwise specified.

As used herein, the term “alkyl” or “alkyl group” refers to a radical of a saturated aliphatic functional group, including a linear chain alkyl group, a branched chain alkyl group, a cycloalkyl (alicyclic) group, an alkyl-substituted cycloalkyl group, and a cycloalkyl-substituted alkyl group, which has 1 to 60 carbons linked by a single bond unless otherwise specified.

As used herein, the term “haloalkyl group” or “halogenalkyl group” refers to an alkyl group in which a halogen is substituted, unless otherwise specified.

As used herein, the term “alkenyl” or “alkynyl” has a double bond or triple bond, respectively, includes a linear or branched chain group, and has 2 to 60 carbon atoms unless otherwise specified, but is not limited thereto.

As used herein, the term “cycloalkyl” refers to an alkyl which forms a ring having 3 to 60 carbon atoms unless otherwise specified, but is not limited thereto.

As used herein, the term “alkoxy group” or “alkyloxy group” refers to an alkyl group to which an oxygen radical is linked, and has 1 to 60 carbon atoms unless otherwise specified, but is not limited thereto.

As used herein, the term “alkenoxyl group”, “alkenoxy group”, “alkenyloxyl group”, or “alkenyloxy group” refers to an alkenyl group to which an oxygen radical is linked, and has 2 to 60 carbon atoms unless otherwise specified, but is not limited thereto.

As used herein, the terms “aryl group” and “arylene group” each have 6 to 60 carbon atoms unless otherwise specified, but are not limited thereto. As used herein, the aryl group or arylene group includes a single ring type, a ring assembly, a fused multiple ring compound, etc. For example, the aryl group may include a phenyl group, a monovalent functional group of biphenyl, a monovalent functional group of naphthalene, a fluorenyl group, and a substituted fluorenyl group, and the arylene group may include a fluorenylene group and a substituted fluorenylene group.

As used herein, the term “ring assembly” means that two or more ring systems (monocyclic or fused ring systems) are directly connected to each other through a single bond or double bond, in which the number of direct links between such rings is one less than the total number of ring systems in the compound. In the ring assembly, the same or different ring systems may be directly connected to each other through a single bond or double bond.

As used herein, since the aryl group includes a ring assembly, the aryl group includes biphenyl and terphenyl in which a benzene ring, which is a single aromatic ring, is connected by a single bond. Additionally, since the aryl group also includes a compound in which an aromatic ring system fused to an aromatic single ring is connected by a single bond, it also includes, for example, a compound in which a benzene ring (which is a single aromatic ring) and fluorine (which is a fused aromatic ring system) are linked by a single bond.

As used herein, the term “fused multiple ring system” refers to a fused ring form in which at least two atoms are shared, and it includes a form in which ring systems of two or more hydrocarbons are fused, a form in which at least one heterocyclic system including at least one heteroatom is fused, etc. Such a fused multiple ring system may be an aromatic ring, a heteroaromatic ring, an aliphatic ring, or a combination of these rings. For example, in the case of an aryl group, it may be a naphthalenyl group, a phenanthrenyl group, a fluorenyl group, etc., but is not limited thereto.

As used herein, the term “a spiro compound” has a spiro union, and the spiro union refers to a linkage in which two rings share only one atom. In particular, the atom shared by the two rings is called a “spiro atom”, and they are each called “monospiro-”, “dispiro-”, and “trispiro-” compounds depending on the number of spiro atoms included in a compound.

As used herein, the terms “fluorenyl group”, “fluorenylene group”, and “fluorenetriyl group” refer to a monovalent, divalent, or trivalent functional group in which R, R′, R″, and R′″ are all hydrogen in the following structures, respectively, unless otherwise specified; “substituted fluorenyl group”, “substituted fluorenylene group”, or “substituted fluorenetriyl group” means that at least one of the substituents R, R′, R″, and R′″ is a substituent other than hydrogen, and includes cases where R and R′ are bound to each other to form a spiro compound together with the carbon to which they are linked. As used herein, all of the fluorenyl group, the fluorenylene group, and the fluorenetriyl group may also be referred to as a fluorene group regardless of valences such as monovalent, divalent, trivalent, etc.

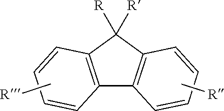

Additionally, the R, R′, R″, and R′″ may each independently be an alkyl group having 1 to 20 carbon atoms, an alkenyl group having 1 to 20 carbon atoms, an aryl group having 6 to 30 carbon atoms, and a heterocyclic group having 2 to 30 carbon atoms and, for example, the aryl group may be phenyl, biphenyl, naphthalene, anthracene, or phenanthrene, and the heterocyclic group may be pyrrole, furan, thiophene, pyrazole, imidazole, triazole, pyridine, pyrimidine, pyridazine, pyrazine, triazine, indole, benzofuran, quinazoline, or quinoxaline. For example, the substituted fluorenyl group and the fluorenylene group may each be a monovalent functional group or divalent functional group of 9,9-dimethylfluorene, 9,9-diphenylfluorene, and 9,9′-spirobi[9H-fluorene].

As used herein, the term “heterocyclic group” includes not only aromatic rings (e.g., “heteroaryl group” and “heteroarylene group”), but also non-aromatic rings, and may refer to a ring having 2 to 60 carbon atoms each including one or more heteroatoms unless otherwise specified, but is not limited thereto. As used herein, the term “heteroatom” refers to N, O, S, P, or Si unless otherwise specified, and a heterocyclic group refers to a monocyclic group including a heteroatom, a ring assembly, a fused multiple ring system, a spiro compound, etc.

For example, the “heterocyclic group” may include a compound including a heteroatom group (e.g., SO₂, P═O, etc.), such as the compound shown below, instead of carbon that forms a ring.

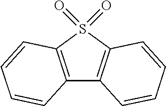 [SMILES: O=S1(=O)c2ccccc2-c2ccccc21]

As used herein, the term “ring” includes monocyclic and polycyclic rings, and includes heterocycles containing at least one heteroatom as well as hydrocarbon rings, and includes aromatic and non-aromatic rings.

As used herein, the term “polycyclic” includes ring assemblies (e.g., biphenyl, terphenyl, etc.), fused multiple ring systems, and spiro compounds, includes non-aromatic as well as aromatic compounds, and includes heterocycles containing at least one heteroatom as well as hydrocarbon rings.

As used herein, the term “alicyclic group” refers to cyclic hydrocarbons other than aromatic hydrocarbons, and it includes monocyclic, ring assemblies, fused multiple ring systems, spiro compounds, etc., and refers to a ring having 3 to 60 carbon atoms unless otherwise specified, but is not limited thereto. For example, when benzene (i.e., an aromatic ring) and cyclohexane (i.e., a non-aromatic ring) are fused, it also corresponds to an aliphatic ring.

Additionally, when prefixes are named consecutively, it means that the substituents are listed in the order they are described. For example, in the case of an arylalkoxy group, it means an alkoxy group substituted with an aryl group; in the case of an alkoxycarbonyl group, it means a carbonyl group substituted with an alkoxy group; additionally, in the case of an arylcarbonyl alkenyl group, it means an alkenyl group substituted with an arylcarbonyl group, in which the arylcarbonyl group is a carbonyl group substituted with an aryl group.

Additionally, unless otherwise specified, the term “substituted” in the expression “substituted or unsubstituted” as used herein refers to a substitution with one or more substituents selected from the group consisting of deuterium, a halogen, an amino group, a nitrile group, a nitro group, a C₁₋₃₀ alkyl group, a C₁₋₃₀ alkoxy group, a C₁₋₃₀ alkylamine group, a C₁₋₃₀ alkylthiophene group, a C₆₋₃₀ arylthiophene group, a C₂₋₃₀ alkenyl group, a C₂₋₃₀ alkynyl group, a C₃₋₃₀ cycloalkyl group, a C₆₋₃₀ aryl group, a C₆₋₃₀ aryl group substituted with deuterium, a C₈₋₃₀ arylalkenyl group, a silane group, a boron group, a germanium group, and a C₂₋₃₀ heterocyclic group containing one or more heteroatoms selected from the group consisting of O, N, S, Si, and P, but is not limited to these substituents.

As used herein, the “names of functional groups” corresponding to the aryl group, arylene group, heterocyclic group, etc. exemplified as examples of each symbol and a substituent thereof may be described as “a name of the functional group reflecting its valence”, and may also be described as the “name of its parent compound”. For example, in the case of “phenanthrene”, which is a type of an aryl group, the names of the groups may be described such that the monovalent group is described as “phenanthryl (group)”, and the divalent group is described as “phenanthrylene (group)”, etc., but may also be described as “phenanthrene”, which is the name of its parent compound, regardless of its valence.

Similarly, in the case of pyrimidine as well, it may be described regardless of its valence, or in the case of being monovalent, it may be described as pyrimidinyl (group); and in the case of being divalent, it may be described as the “name of the group” of the valence (e.g., pyrimidinylene (group)). Therefore, as used herein, when the type of a substituent is described as the name of its parent compound, it may refer to an n-valent “group” formed by detachment of a hydrogen atom linked to a carbon atom and/or hetero atom of its parent compound.

Additionally, in describing the names of the compounds or the substituents in the present specification, the numbers, letters, etc. indicating positions may be omitted. For example, pyrido[4,3-d]pyrimidine may be described as pyridopyrimidine; benzofuro[2,3-d]pyrimidine as benzofuropyrimidine; 9,9-dimethyl-9H-fluorene as dimethylfluorene, etc. Therefore, both benzo[g]quinoxaline and benzo[f]quinoxaline may be described as benzoquinoxaline.

Additionally, unless there is an explicit description, the formulas used in the present disclosure are applied in the same manner as in the definition of substituents by the exponent definition of the formula below.

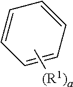

In particular, when a is an integer of 0, it means that the substituent R¹ is absent, that is, when a is 0, it means that hydrogens are linked to all carbons that form a benzene ring, and in this case, the formula or compound may be described while omitting the indication of the hydrogen linked to the carbon. Additionally, when a is an integer of 1, one substituent R¹ may be linked to any one of the carbons forming a benzene ring; when a is an integer of 2 or 3, it may be linked, for example, as shown below; even when a is an integer of 4 to 6, it may be linked to the carbon of a benzene ring in a similar manner; and when a is an integer of 2 or greater, R¹ may be the same as or different from each other.

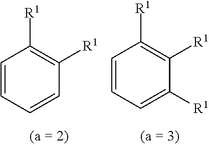

Unless otherwise specified in the present application, forming a ring means that neighboring groups bind to one another to form a single ring or fused multiple ring, and the single ring and the formed fused multiple ring include a heterocycle containing at least one heteroatom as well as a hydrocarbon ring, and may include aromatic and non-aromatic rings.

Additionally, unless otherwise specified in the present specification, when indicating a condensed ring, the number in “number-condensed ring” indicates the number of rings to be condensed. For example, a form in which three rings are condensed with one another (e.g., anthracene, phenanthrene, benzoquinazoline, etc.) may be expressed as a 3-condensed ring.

Meanwhile, as used herein, the term “bridged bicyclic compound” refers to a compound in which two rings share 3 or more atoms to form a ring, unless otherwise specified. In particular, the shared atoms may include carbon or a hetero atom.

In the present disclosure, an organic electric device may refer to a component(s) between a positive electrode and a negative electrode, or may refer to an organic light emitting diode which includes a positive electrode, a negative electrode, and a component(s) disposed therebetween.

Additionally, in some cases, the display device in the present disclosure may refer to an organic electric device, an organic light emitting diode, and a panel including the same, or may refer to an electronic device including a panel and a circuit. In particular, for example, the electronic device may include a lighting device, a solar cell, a portable or mobile terminal (e.g., a smart phone, a tablet, a PDA, an electronic dictionary, a PMP, etc.), a navigation terminal, a game machine, various TV sets, various computer monitors, etc., but is not limited thereto, and may be any type of device as long as it includes the component(s).

Hereinafter, embodiments of the present disclosure will be described in detail. However, these embodiments are provided for illustrative purposes, and the present disclosure is not limited thereby, and the present disclosure is only defined by the scope of the claims to be described later.

The photosensitive resin composition according to an embodiment of the present disclosure includes an alkali-soluble resin; a reactive unsaturated compound; a photoinitiator having a maximum molar absorption coefficient of 10,000 (L/mol·cm) or more in the region of 320 nm to 380 nm and a loss of 5 wt % at 200° C. or less; a colorant; and a solvent.

Preferably, the alkali-soluble resin includes a repeating unit represented by Formula (1) below.

### (1) Alkali-Soluble Resin

The binder resin according to an embodiment of the present disclosure includes a repeating unit of the same structure as Formula (1) below.

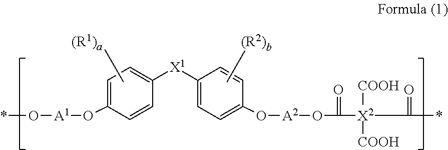

In Formula (1) above,
1) * indicates a moiety where a bond is connected as a repeating unit,
2) R¹ and R² are each independently hydrogen; deuterium; halogen; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₃₀ alkyl group; a C₂₋₃₀ alkenyl group; a C₂₋₃₀ alkynyl group; a C₁₋₃₀ alkoxy group; a C₆₋₃₀ aryloxy group; a fluorenyl group; a carbonyl group; an ether group; or a C₁₋₃₀ alkoxycarbonyl group,
3) R¹ and R² may each form a ring with neighboring groups,
4) a and b are each independently an integer from 0 to 4,
5) X¹ is a single bond, O, CO, SO₂, CR′R″, SiR′R″, Formula (A), or Formula (B); preferably Formula (A), or Formula (B); and more preferably Formula (A),
6) X² is a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₃₀ alkyl group; a C₂₋₃₀ alkenyl group; a C₂₋₃₀ alkynyl group; a C₁₋₃₀ alkoxy group; a C₆₋₃₀ aryloxy group; or a combination thereof,
7) R′ and R″ are each independently hydrogen; deuterium; halogen; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₃₀ alkyl group; a C₂₋₃₀ alkenyl group; a C₂₋₃₀ alkynyl group; a C₁₋₃₀ alkoxy group; a C₆₋₃₀ aryloxy group; a fluorenyl group; a carbonyl group; an ether group; or a C₁₋₃₀ alkoxycarbonyl group,
8) R′ and R″ may each form a ring with neighboring groups,
9) A¹ and A² are each independently Formula (C) or Formula (D), and
10) the ratio of Formula (C) to Formula (D) in the polymer chain of the resin including the repeating unit represented by Formula (1) meets 1:9 to 9:1.

Examples in which R′ and R″ bind to each other to form a ring are as follows.

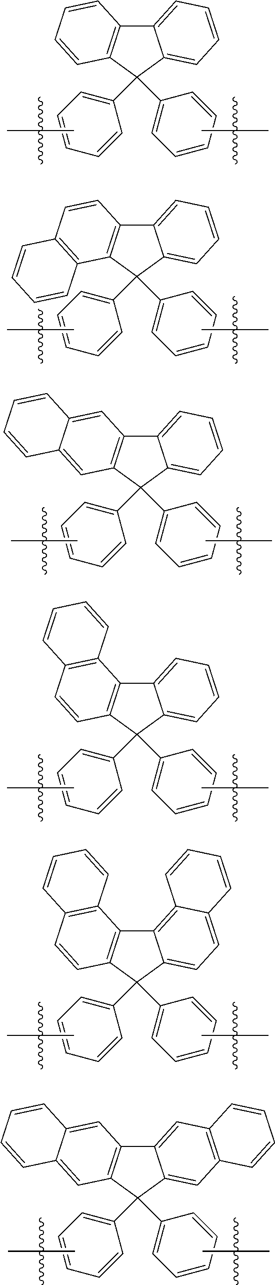

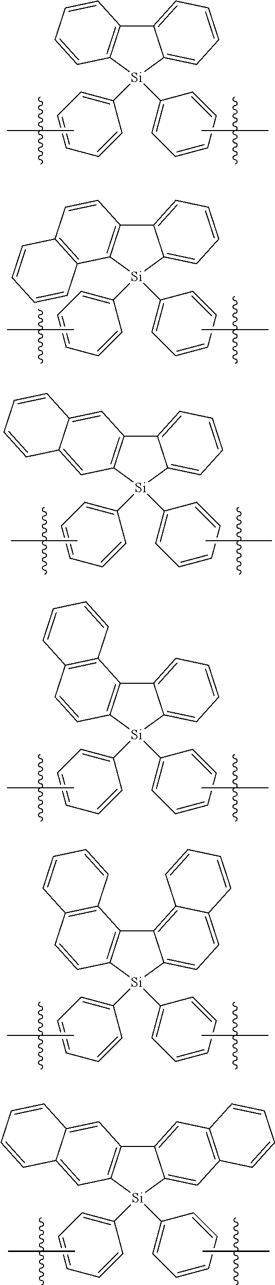

Specific examples of the above-mentioned formulas (A) and (B) are as follows.

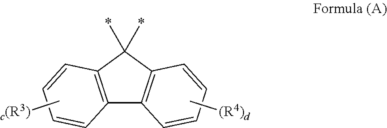

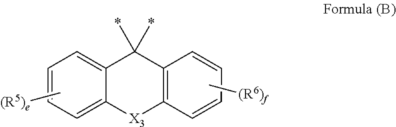

In Formula (A) and Formula (B) above,
11-1) * indicates a binding position,
11-2) X³ is O, S, SO₂, or NR′,
11-3) R′ is hydrogen; deuterium; halogen; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₃₀ alkyl group; a C₂₋₃₀ alkenyl group; a C₂₋₃₀ alkynyl group; a C₁₋₃₀ alkoxy group; a C₆₋₃₀ aryloxy group; a fluorenyl group; a carbonyl group; an ether group; or a C₁₋₃₀ alkoxycarbonyl group,
11-4) R³ to R⁶ are each independently hydrogen; deuterium; halogen; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₃₀ alkyl group; a C₂₋₃₀ alkenyl group; a C₂₋₃₀ alkynyl group; a C₁₋₃₀ alkoxy group; a C₆₋₃₀ aryloxy group; a fluorenyl group; a carbonyl group; an ether group; or a C₁₋₃₀ alkoxycarbonyl group,
11-5) R³ to R⁶ may each form a ring with neighboring groups, and
11-6) c to f are each independently an integer from 0 to 4.

Specific examples of Formula (C) and Formula (D) mentioned above are as follows.

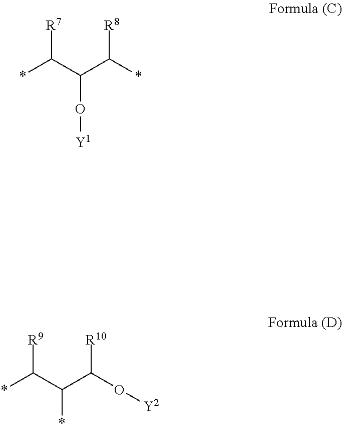

In Formula (C) and Formula (D) above,
12-1) * indicates a binding position,
12-2) R⁷ to R¹⁰ are each independently hydrogen; deuterium; halogen; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₃₀ alkyl group; a C₂₋₃₀ alkenyl group; a C₂₋₃₀ alkynyl group; a C₁₋₃₀ alkoxy group; a C₆₋₃₀ aryloxy group; a fluorenyl group; a carbonyl group; an ether group; or a C₁₋₃₀ alkoxycarbonyl group, and
12-3) Y¹ and Y² are each independently Formula (E) or Formula (F).

Specific examples of Formula (E) or Formula (F) mentioned above are as follows.

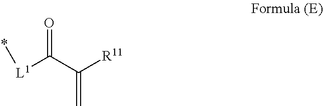

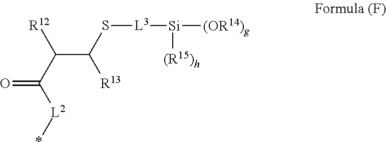

In Formula (E) and Formula (F) above,
13-1) * indicates a binding position,
13-2) R¹¹ to R¹⁵ are each independently hydrogen; deuterium; halogen; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₃₀ alkyl group; a C₂₋₃₀ alkenyl group; a C₂₋₃₀ alkynyl group; a C₁₋₃₀ alkoxy group; a C₆₋₃₀ aryloxy group; a fluorenyl group; a carbonyl group; an ether group; or a C₁₋₃₀ alkoxycarbonyl group,
13-3) L¹ to L³ are each independently a single bond, C₁₋₃₀ alkylene, C₆₋₃₀ arylene, or a C₂₋₃₀ heterocyclic ring, and
13-4) g and h are each independently an integer from 0 to 3; with the proviso that the sum of g+h=3, and
14) the R¹ to R¹⁵, R′, R″, X¹, X², and L¹ to L³ and the ring formed between the neighboring substituents may each be further substituted with one or more substituents selected from the group consisting of deuterium; halogen; a silane group substituted or unsubstituted with a C₁₋₃₀ alkyl group or C₆₋₃₀ aryl group; a siloxane group; a boron group; a germanium group; a cyano group; an amino group; a nitro group; a C₁₋₃₀ alkylthio group; a C₁₋₃₀ alkoxy group; a C₆₋₃₀ arylalkoxy group; a C₁₋₃₀ alkyl group; a C₂₋₃₀ alkenyl group; a C₂₋₃₀ alkynyl group; a C₆₋₃₀ aryl group; a C₆₋₃₀ aryl group substituted with deuterium; a fluorenyl group; a C₂₋₃₀ heterocyclic group including at least one heteroatom among O, N, S, Si, and P; a C₃₋₃₀ alicyclic group; a C₇₋₃₀ arylalkyl group; a C₈₋₃₀ arylalkenyl group; and a combination thereof; or may form a ring between the neighboring substituents.

When R¹ to R¹⁵, R′, R″, X¹, and X² are aryl groups, these may preferably be a C₆₋₃₀ aryl group, more preferably a C₆₋₁₈ aryl group, for example, phenyl, biphenyl, naphthyl, terphenyl, etc.

Where R¹ to R¹⁵, R′, R″, X¹, X², and L¹ to L³ are heterocyclic groups, these may preferably be a C₂₋₃₀ heterocyclic group, and more preferably a C₂₋₁₈ heterocyclic group, for example, dibenzofuran, dibenzothiophene, naphthobenzothiophene, naphthobenzofuran, etc.

When R¹ to R¹⁵, R′, R″, X¹, and X² are fluorenyl groups, these may preferably be 9,9-dimethyl-9H-fluorene, a 9,9-diphenyl-9H-fluorenyl group, 9,9′-spirobifluorene, etc.

Where L¹ to L³ are arylene groups, these may preferably be a C₆₋₃₀ arylene group, and more preferably a C₆₋₁₈ arylene groups, for example, phenyl, biphenyl, naphthyl, terphenyl, etc.

Where R¹ to R¹⁵, R′, and R″ are alkyl groups, these may preferably be a C₁₋₁₀ alkyl group, for example, methyl, t-butyl, etc.

Where R¹ to R¹⁵, R′, and R″ are alkoxyl groups, these may preferably be a C₁₋₃₀ alkoxyl group, and more preferably a C₁₋₁₀ alkoxyl group, for example, methoxy, t-butoxy, etc.

The rings formed by the binding among the neighboring groups of R¹ to R¹⁵, R′, R″, X¹, X², and L¹ to one another may be a C₆₋₆₀ aromatic ring group; a fluorenyl group; a C₂₋₆₀ heterocyclic group including at least one heteroatom among O, N, S, Si, and P; or a C₃₋₆₀ alicyclic group, for example, when the neighboring groups bind with one another to form an aromatic ring; preferably, a C₆₋₃₀ aromatic ring, more preferably a C₆₋₁₄ aromatic ring, for example, benzene, naphthalene, phenanthrene, etc. may be formed.

The ratio of Formula (E) to Formula (F) in the polymer chain of the resin including the repeating unit represented by Formula (1) is preferably 2:0 to 1:1, and most preferably, it is a ratio of 1.5:0.5. When the ratio of Formula (F) is higher than the ratio of Formula (E), a residue may be generated due to the overly increased adhesion, the amount of outgas generated may also be significantly increased, whereas when the ratio of Formula (E) to Formula (F) is 1.5:0.5, the resolution of the pattern is most excellent and the amount of outgas can be satisfied

The weight average molecular weight of the resin of the present disclosure may be 1,000 g/mol to 100,000 g/mol, preferably 1,000 g/mol to 50,000 g/mol, and more preferably 1,000 g/mol to 30,000 g/mol. When the weight average molecular weight of the resin is within the above range, the pattern can be well formed without a residue during the preparation of the pattern layer, there is no loss of film thickness during development, and a good pattern can be obtained.

The resin may be included in an amount of 1 wt % to 30 wt %, and more preferably 3 wt % to 20 wt %, based on the total amount of the photosensitive resin composition. When the resin is included within the above range, excellent sensitivity, developability, and adhesion (cohesion) can be obtained.

The photosensitive resin composition may further include an acryl-based resin in addition to the resin. The acryl-based resin is a copolymer of a first ethylenically unsaturated monomer and a second ethylenically unsaturated monomer copolymerizable therewith, and may be a resin including one or more acryl-based repeating units.

### (2) Reactive Unsaturated Compounds

The photosensitive resin composition according to an embodiment of the present disclosure includes a reactive unsaturated compound having a structure as shown in Formula (2) below.

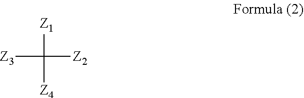

In Formula (2) above, two or more of Z₁ to Z₄ independently have a structure of Formula (G); the remaining Z₁ to Z₄ are independently hydrogen, deuterium, halogen, a methyl group, an ethyl group; a methyl hydroxy group; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₃₀ alkyl group; a C₂₋₃₀ alkenyl group; a C₂₋₃₀ alkynyl group; a C₁₋₃₀ alkoxy group; a C₆₋₃₀ aryloxy group; a fluorenyl group; a carbonyl group; an ether group; or a C₁₋₃₀ alkoxycarbonyl group.

Specific examples of the above-mentioned formula (G) are as follows.

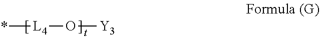

In Formula (G) above,
1) t is an integer of 1 to 20,
2) L₄ is a single bond, C₁₋₃₀ alkylene, C₆₋₃₀ arylene, or a C₂₋₃₀ heterocyclic ring, and
3) Y₃ is Formula (H) or Formula (I) below.

Specific examples of the above-mentioned formula (H) or formula (I) are as follows.

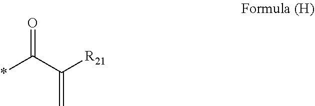

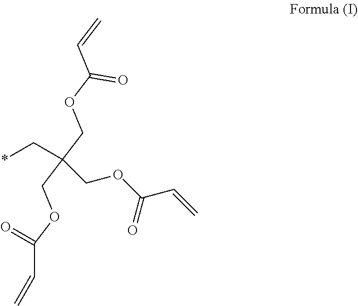 [SMILES: *CC(COC(=O)C=C)(COC(=O)C=C)COC(=O)C=C]

In Formula (H) above, R₂₁ is hydrogen; deuterium; halogen; a methyl group; an ethyl group; a methyl hydroxy group; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₃₀ alkyl group; a C₂₋₃₀ alkenyl group; a C₂₋₃₀ alkynyl group; a C₁₋₃₀ alkoxy group; a C₆₋₃₀ aryloxy group; a fluorenyl group; a carbonyl group; an ether group; or a C₁₋₃₀ alkoxycarbonyl group.

The multi-acryl-based compound having the structure as in Formula (2) may be used alone or in combination of two or more. For example, polyfunctional esters of (meth)acrylic acid having at least two ethylenically unsaturated double bonds may be used.

As used herein, “(meth)acrylic acid” may refer to methacrylic acid, acrylic acid, or a mixture of methacrylic acid and acrylic acid.

Since the reactive unsaturated compound has the ethylenically unsaturated double bond, it is possible to form a pattern excellent in heat resistance, light resistance, and chemical resistance by causing sufficient polymerization during exposure to light in the pattern forming process.

Specific examples of the reactive unsaturated compound may be one or more selected from ethylene glycol diacrylate, ethylene glycol dimethacrylate, diethylene glycol diacrylate, triethylene glycol diacrylate, triethylene glycol dimethacrylate, 1,6-hexanediol diacrylate, 1,6-hexanediol dimethacrylate, pentaerythritol triacrylate, dipentaerythritol pentaacrylate, dipentaerythritol hexaacrylate, bisphenol A epoxy acrylate, ethylene glycol monomethyl ether acrylate, trimethylolpropane triacrylate, tripentaerythritol octaacrylate, etc., but is not limited thereto.

Examples of commercially available products of the reactive unsaturated compound are as follows.

Examples of the bifunctional ester of (meth)acrylic acid may include Aronix M-210, M-240, M-6200, etc. (Toa Kosei Kagaku Kogyo Co., Ltd.), KAYARAD HDDA, HX-220, R-604, etc. (Nippon Kayaku Co., Ltd.), and V-260, V-312, V-335 HP, etc. (Osaka Yuki Kagaku Kogyo Co., Ltd.).

Examples of the trifunctional ester of (meth)acrylic acid include M-309, M-400, M-405, M-450, M-7100, M-8030, M-8060 (Toa Kosei Kagaku Kogyo Co., Ltd.), KAYARAD TMPTA, DPCA-30, DPCA-60, DPCA-120, etc. (Nippon Kayaku Co., Ltd.), and V-295, V-300, V-360, etc. (Osaka Yuki Kagaku Kogyo Co., Ltd.).

These products may be used alone or in combination of two or more.

The reactive unsaturated compound may be used after treating with an acid anhydride so as to provide improved developability. The reactive unsaturated compound may be included in an amount of 1 wt % to 40 wt %, for example, 1 wt % to 20 wt %, based on the total amount of the photosensitive composition. When the reactive unsaturated compound is included within the above range, sufficient curing occurs during exposure to light in the pattern forming process, thus obtaining excellent reliability, excellent heat resistance, light resistance, and chemical resistance of the pattern, and also excellent resolution and adhesion.

### (3) Photoinitiator

In order to implement a negative pattern by photolithography, it is necessary to use a photoradical initiator. The photoinitiator has a maximum molar absorption coefficient of 10,000 (L/mol·cm) or more in the region of 320 nm to 380 nm and a loss of 5 wt % at 200° C. or less. In particular, the maximum molar extinction coefficient in the region of 320 nm to 380 nm may be calculated by the Beer-Lambert law. Additionally, the weight loss was measured by raising the temperature to 300° C. at a rate of 5° C. per minute in a nitrogen atmosphere using TGA.

The photosensitive resin composition according to an embodiment of the present disclosure includes a photoinitiator having a structure as shown in Formula (3) below.

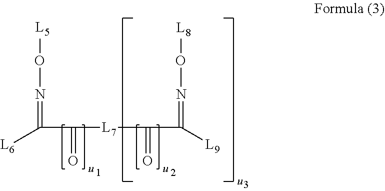

1) u₁ to u₃ are each independently an integer of 0 or 1,
2) L₅ and L₈ are the following formula (J),
3) L₆, L₇, and L₉ are each independently a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₃₋₃₀ alicyclic group; a C₁₋₃₀ alkyl group; a C₂₋₃₀ alkenyl group; a C₂₋₃₀ alkynyl group; a C₁₋₃₀ alkoxy group; a C₆₋₃₀ aryloxy group; a fluorenyl group; a carbonyl group; an ether group; a C₁₋₃₀ alkoxycarbonyl group; C₁₋₃₀ alkylene; or C₆₋₃₀ arylene group; or a combination thereof.

Specific examples of the above-mentioned Formula (J) is as follows.

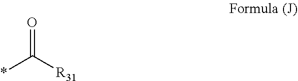

In Formula (J) above,
1) * is indicates a binding position,
2) R₃₁ is hydrogen; deuterium; halogen; a methyl group; an ethyl group; a methyl hydroxy group; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₃₀ alkyl group; a C₂₋₃₀ alkenyl group; a C₂₋₃₀ alkynyl group; a C₁₋₃₀ alkoxy group; a C₆₋₃₀ aryloxy group; a fluorenyl group; a carbonyl group; an ether group; or a C₁₋₃₀ alkoxycarbonyl group.

Additionally, it is more preferable that L₆, L₇, and L₉ of Formula (3) above are each independently one of the following Formulas (K) to (N).

Specific examples of the above-mentioned Formulas (K) to (N) are as follows.

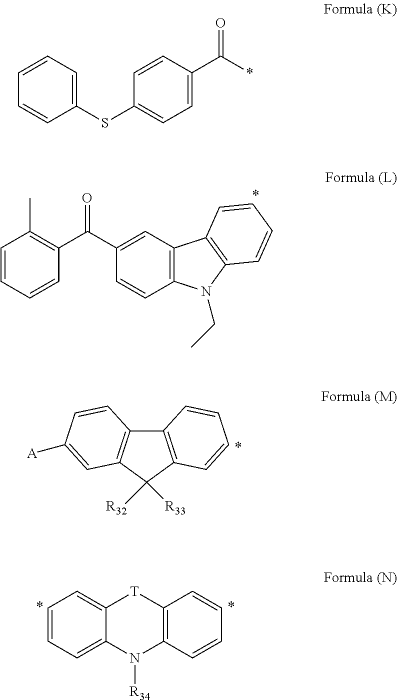

In Formulas (M) and (N) above,
1) * is indicated binding position,
2) A is hydrogen; O; S; a silane group; a siloxane group; a boron group; a germanium group; a cyano group; a nitro group; a nitrile group; an amino group substituted or unsubstituted with a C₁₋₃₀ alkyl group, a C₆₋₃₀ aryl group, or a C₂₋₃₀ heterocyclic group; a C₁₋₃₀ alkylthio group; a C₁₋₃₀ alkyl group; a C₁₋₃₀ alkoxy group; a C₆₋₃₀ arylalkoxy group; a C₂₋₃₀ alkenyl group; a C₂₋₃₀ alkynyl group; a C₆₋₃₀ aryl group; a C₆₋₃₀ aryl group substituted with deuterium; a fluorenyl group; a C₂₋₃₀ heterocyclic group including at least one heteroatom among O, N, S, Si, and P; a C₃₋₃₀ alicyclic group; a C₇₋₃₀ arylalkyl group; a C₈₋₃₀ arylalkenyl group; and a combination thereof,
3) R₃₂ to R₃₄ are each independently hydrogen; deuterium; halogen; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₃₀ alkyl group; a C₂₋₃₀ alkenyl group; a C₂₋₃₀ alkynyl group; a C₁₋₃₀ alkoxy group; a C₆₋₃₀ aryloxy group; a fluorenyl group; a carbonyl group; an ether group; or a C₁₋₃₀ alkoxycarbonyl group, and
4) T is S, O, or Se.

In the photosensitive resin composition according to an embodiment of the present disclosure, the oxime ester-based compound of Formula (3) above may be used alone or in combination of two or more.

The photoinitiator that can be used in combination with the oxime ester-based compound is a photoinitiator used in a photosensitive resin composition, for example, an acetophenone-based compound, a benzophenone-based compound, a thioxanthone-based compound, a benzoin-based compound, a triazine-based compound, etc. may be used.

Examples of the acetophenone-based compound may include 2,2′-diethoxy acetophenone, 2,2′-dibutoxy acetophenone, 2-hydroxy-2-methylpropiophenone, p-t-butyltrichloro acetophenone, p-t-butyldichloro acetophenone, 4-chloro acetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)-butan-1-one, etc.

Examples of the benzophenone-based compound may include benzophenone, benzoyl benzoate, methyl benzoyl benzoate, 4-phenyl benzophenone, hydroxy benzophenone, acrylated benzophenone, 4,4′-bis(dimethylamino)benzophenone, 4,4′-bisdiethylamino)benzophenone, 4,4′-dimethylaminobenzophenone, 4,4′-dichlorobenzophenone, 3,3′-dimethyl-2-methoxybenzophenone, etc.

Examples of the thioxanthone-based compound may include thioxanthone, 2-chlorothioxanthone, 2-methylthioxanthone, isopropyl thioxanthone, 2,4-diethyl thioxanthone, 2,4-diisopropyl thioxanthone, 2-chlorothioxanthone, etc.

Examples of the benzoin-based compound may include benzoin, benzoin methyl ether, benzoin ethyl ether, benzoin isopropyl ether, benzoin isobutyl ether, benzyldimethyl ketal, etc.

Examples of the triazine-based compound may include 2,4,6-trichloro-s-triazine, 2-phenyl 4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloromethyl)-s-triazine; 2-biphenyl 4,6-bis(trichloromethyl)-s-triazine, bis(trichloromethyl)-6-styryl-s-triazine, 2-(naphthol-yl)-4,6-bis(trichloromethyl)-s-triazine, 2-(4-methoxynaphthol-yl)-4,6-bis(trichloromethyl)-s-triazine, 2-4-trichloromethyl(piperonyl)-6-triazine, 2-4-trichloromethyl(4′-methoxystyryl)-6-triazine, etc.

As the photoinitiator, a carbazole-based compound, a diketone-based compound, a sulfonium borate-based compound, a diazo-based compound, an imidazole-based compound, a non-imidazole-based compound, etc. may be used in addition to the compounds described above.

As the photoinitiator, which is a radical polymerization initiator, a peroxide-based compound, an azobis-based compound, etc. may be used.

Examples of the peroxide-based compound may include ketone peroxides (e.g., methyl ethyl ketone peroxide, methyl isobutyl ketone peroxide, cyclohexanone peroxide, methylcyclohexanone peroxide, acetylacetone peroxide, etc.); diacyl peroxides (e.g., isobutyryl peroxide, 2,4-dichlorobenzoyl peroxide, o-methylbenzoyl peroxide, bis-3,5,5-trimethylhexanoyl peroxide, etc.); hydroperoxides (e.g., 2,4,4,-trimethylpentyl-2-hydroperoxide, diisopropylbenzene hydroperoxide, cumene hydroperoxide, t-butyl hydroperoxide, etc.); dialkyl peroxides (e.g., dicumyl peroxide, 2,5-dimethyl-2,5-di(t-butylperoxy)hexane, 1,3-bis(1-butyloxyisopropyl)benzene, t-butylperoxyvalerate n-butyl ester, etc.); alkyl peresters (e.g., 2,4,4-trimethylpentyl peroxyphenoxyacetate, α-cumyl peroxyneodecanoate, t-butyl peroxybenzoate, di-t-butyl peroxytrimethyl adipate, etc.); percarbonates (e.g., di-3-methoxybutyl peroxydicarbonate, di-2-ethylhexyl peroxydicarbonate, bis-4-t-butylcyclohexyl peroxydicarbonate, diisopropyl peroxydicarbonate, acetylcyclohexylsulfonyl peroxide, 1-butyl peroxyaryl carbonate, etc.), etc.

Examples of the azobis-based compound may include 1,1′-azobiscyclohexan-1-carbonitrile, 2,2′-azobis(2,4-dimethylvaleronitrile), 2,2,-azobis(methylisobutyrate), 2,2′-azobis(4-methoxy-2,4-dimethylvaleronitrile), α,α′-azobis(isobutylnitrile), 4,4′-azobis(4-cyanovaleric acid), etc.

The photoinitiator may be used together with a photosensitizer that causes a chemical reaction by absorbing light to enter an excited state and then transferring the energy. Examples of the photosensitizer may include tetraethylene glycol bis-3-mercaptopropionate, pentaerythritol tetrakis-3-mercaptopropionate, dipentaerythritol tetrakis-3-mercaptopropionate, etc.

The maximum molar absorption coefficient in the 320 nm to 380 nm region of the photoinitiator is preferably 10,000 L/mol·cm or more, and more preferably 5,000 L/mol·cm to 40,000 L/mol·cm. When the maximum molar extinction coefficient in the region of 320 nm to 380 nm of the photoinitiator is 5,000 L/mol·cm to 40,000 L/mol·cm, there is an advantage in that the patternability is excellent due to high sensitivity. In contrast, when the maximum molar extinction coefficient in the 320 nm to 380 nm region is less than 5,000 L/mol·cm, there is a problem in that the pattern is not properly formed in the exposure step due to low sensitivity, whereas when the maximum molar extinction coefficient in the 320 nm to 380 nm region exceeds 40,000 L/mol·cm, it is difficult to adjust the pattern size and the hole size by adjusting the exposure amount in the exposure step.

The temperature of the photoinitiator for 5 wt % reduction of weight is preferably 200° C. or less, and more preferably in the range of 150° C. to 200° C. When the temperature of the photoinitiator for 5 wt % reduction of weight is in the range of 150° C. to 200° C., there is an advantage in that the amount of outgas generated is low in the finally formed pattern, whereas when the temperature is below 150° C., there is a problem in storage stability, and when the temperature is 200° C. or higher, the reliability is low due to generation of a high amount of outgas.

The photoinitiator may be included in an amount of 0.01 wt % to 10 wt %, for example 0.1 wt % to 5 wt %, based on the total amount of the photosensitive resin composition. When the photoinitiator is included within the above range, curing occurs sufficiently upon exposure to light in the pattern forming process to thereby obtain excellent reliability, and the pattern has excellent heat resistance, light resistance, and chemical resistance, and also excellent resolution and adhesion, and a decrease in transmittance due to unreacted initiators can be prevented.

### (4) Reactive Dye

A reactive dye according to an embodiment of the present disclosure is a chromophore-protecting group dye and it includes a reactive dye, which includes a chromophore including the structure represented by Formula (4) below, and a protecting group, which surrounds the chromophore and includes the structure represented by Formula (5) below.

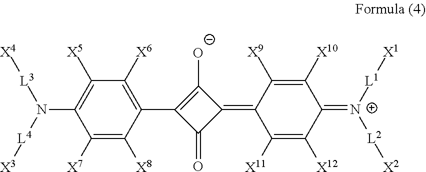

In Formula (4) above,
1) L¹ to L⁴ are each independently a single bond; a fluorenylene group; C₁₋₃₀ alkylene; a C₃₋₃₀ cycloalkylene group; a C₁₋₃₀ alkoxylene group, a C₂₋₃₀ polyethyleneoxy group; a C₆₋₃₀ arylene group; a C₂₋₃₀ heterocyclic ring; or a combination thereof,
2) X¹ to X⁴ are each independently hydrogen; deuterium; a fluorenyl group; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₃₀ alkyl group; a C₂₋₃₀ alkenyl group; a C₂₋₃₀ alkynyl group; a C₁₋₃₀ alkoxy group; a C₆₋₃₀ aryloxy group; a C₃₋₃₀ cycloalkyl group; Formula (4-A); or a combination thereof,
3) at least one of X¹ to X⁴ is Formula (4-A),

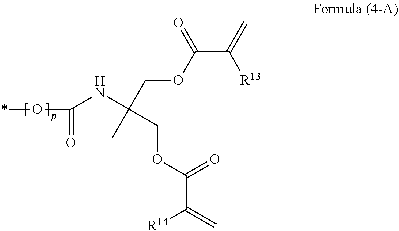

wherein in Formula (4-A) above,
3-1) * is a moiety bonded to L¹ to L⁴ or N,
3-2) p is an integer from 0 to 1,
3-3) when Formula (4-A) is directly bonded to N, p is 0,
3-4) R¹³ and R¹⁴ are independently hydrogen or a methyl group,
4) X⁵ to X¹² are each independently hydrogen; deuterium; halogen; a fluorenyl group; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₃₀ alkyl group; a C₂₋₃₀ alkenyl group; a C₂₋₃₀ alkynyl group; a C₁₋₃₀ alkoxy group; a C₆₋₃₀ aryloxy group; a C₃₋₃₀ cycloalkyl group; or a C₁₋₃₀ alkylamine group,
5) X⁵ to X¹² may bind to each other to form a ring,

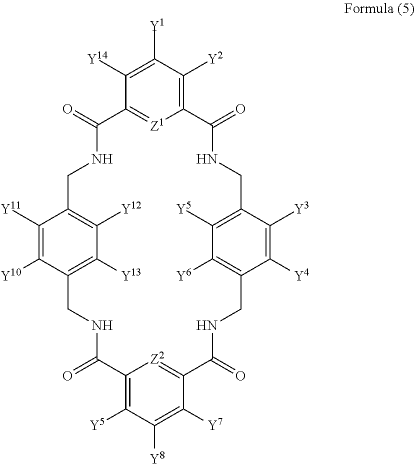

wherein in Formula (5) above,
6) Z¹ and Z² are each independently a carbon atom or a nitrogen atom,
7) Y¹ to Y¹⁴ are each independently hydrogen; deuterium; halogen; a fluorenyl group; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₃₀ alkyl group; a C₂₋₃₀ alkenyl group; a C₂₋₃₀ alkynyl group; a C₁₋₃₀ alkoxy group; a C₆₋₃₀ aryloxy group; a C₃₋₃₀ cycloalkyl group; or a C₁₋₃₀ alkylamine group,
8) Y¹ to Y¹⁴ may bind to each other to form a ring, and
9) the X¹ to X¹⁴, Y¹ to Y¹⁴, and L¹ to L⁴ may each be further substituted with one or more substituents selected from the group consisting of deuterium; halogen; a silane group substituted or unsubstituted with a C₁₋₃₀ alkyl group or C₆₋₃₀ aryl group; a siloxane group; a boron group; a germanium group; a cyano group; an amino group; a nitro group; a C₁₋₃₀ alkylthio group; a C₁₋₃₀ alkoxy group; a C₆₋₃₀ arylalkoxy group; a C₁₋₃₀ alkyl group; a C₂₋₃₀ alkenyl group; a C₂₋₃₀ alkynyl group; a C₆₋₃₀ aryl group; a C₆₋₃₀ aryl group substituted with deuterium; a fluorenyl group; a C₂₋₃₀ heterocyclic group including at least one heteroatom among O, N, S, Si, and P; a C₃₋₃₀ alicyclic group; a C₇₋₃₀ arylalkyl group; a C₈₋₃₀ arylalkenyl group; and a combination thereof; or may form a ring between the neighboring substituents.

In the structure represented by Formula (4) above, when L¹ to L⁴ are polyethyleneoxy groups, the polyethyleneoxy group is preferably any group selected from the group consisting of a monoethyleneoxy group, a diethyleneoxy group, a triethyleneoxy group, a tetraethyleneoxy group, a pentaethyleneoxy groups, a hexaethyleneoxy group, a heptaethyleneoxy group, an octaethyleneoxy group, a nonaethyleneoxy group, a decaethyleneoxy group, an undecaethyleneoxy group, a dodecaethyleneoxy group, a tridecaethyleneoxy group, a tetradecaethyleneoxy group, and a pentadecaethyleneoxy group.

In the structure represented by Formula (4), at least one of X¹ and X² is Formula (4-A), and at least one of X³ and X⁴ is preferably Formula (4-A). More specifically, among the X¹ to X⁴, the remainder where Formula (4-A) is not substituted are preferably each independently selected from the group consisting of an aryl group, an alkyl group, and a cycloalkyl group, and more preferably an aryl group. Most preferably, the aryl group is preferably substituted with an alkyl group. The chromophore-protecting dye of the present disclosure represented by the above structure can secure excellent light resistance.

The chromophore-protecting group dye according to an embodiment is preferable because chemical resistance of the photosensitive composition including the chromophore-protecting group can be secured by introducing a bifunctional acrylate group into both ends of the squalene dye. More specifically, compatibility and coloring power with other components of the photosensitive composition (i.e., an alkali-soluble resin and a reactive unsaturated compound described later) may be secured, and precipitation of the chromophore-protecting dye may be prevented. That is, in the case of the chromophore-protecting group dye of the present disclosure, it has excellent light resistance and chemical resistance and exhibits properties suitable for red or green dyes of color filters.

In the chromophore-protecting group dye, the chromophore including the structure represented by Formula (4) has three resonance structures as shown in Scheme 1 below, but in the present specification, only one resonance structure is shown for convenience purposes.

That is, the chromophore including the structure represented by Formula (4) may be represented by one of the following three resonance structures.

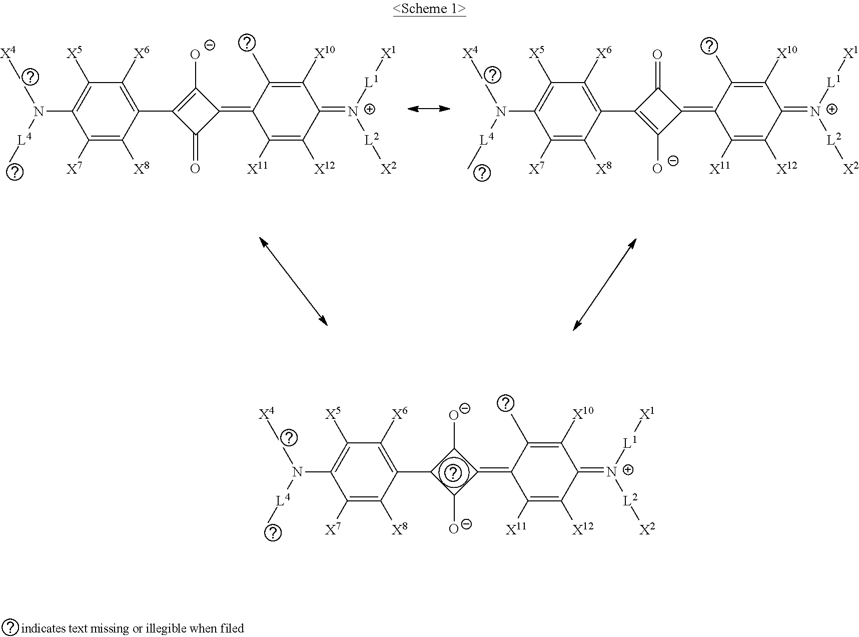

The chromophore including the structure represented by Formula (4) may have a maximum absorption peak at a wavelength of 520 nm to 680 nm. A photosensitive composition for a color filter having high luminance and excellent light resistance can be obtained by way of using the chromophore-protecting group dye containing the chromophore having the spectral characteristics as a green or red dye.

A chromophore-protecting group dye according to an embodiment of the present disclosure has a structure consisting of a chromophore and a protecting group surrounding the chromophore. The protecting group includes a structure represented by Formula (5). Specifically, the protecting group may be a macrocyclic compound, and the protecting group may form a coating layer while surrounding a chromophore having a structure represented by Formula (4).

In an embodiment, the protecting group corresponding to the macrocyclic compound has a structure surrounding a chromophore including the structure represented by Formula (4), that is, by having a structure in which the compound represented by Formula (4) exists inside the macrocycle, the durability of the chromophore-protecting dye can be improved, and accordingly, a color filter having excellent light resistance and chemical resistance can be implemented.

The cage width of the protecting group including the structure represented by Formula (5) may be 6.5 Å to 7.5 Å, and the volume of the protecting group may be 10 Å to 16 Å. In the present specification, the cage width is the inner length of the protecting group, and refers to the distance between the number 1 phenylene group and the number 2 phenylene group in the following Scheme 2 (see Scheme 2). When the protecting group has a cage width within the above range, a chromophore-protecting group dye having a structure surrounding a chromophore including the structure represented by Formula (4) can be obtained, and accordingly, when the chromophore-protecting group dye is added to the photosensitive composition is added, a color filter having excellent durability and high luminance can be implemented.

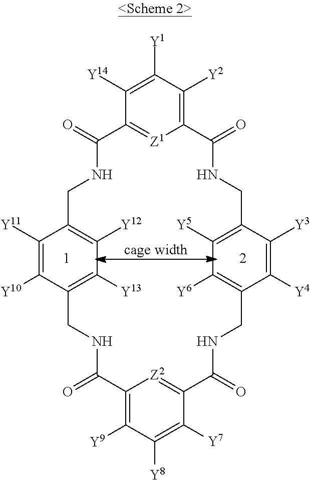

The chromophore-protecting group dye may include a chromophore having a structure represented by Formula (4) and a protecting group having a structure represented by Formula (5) in a 1:1 molar ratio. When the chromophore and the protecting group are present in the above molar ratio, a coating layer (a protecting group) surrounding the chromophore may be well formed. The form, in which the protecting group including the structure represented by Formula (5) surrounds the chromophore including the structure represented by Formula (4), is as shown in Scheme 3 below, in which the rod-shaped chromophore is in a form of penetrating the ring-shaped protecting group.

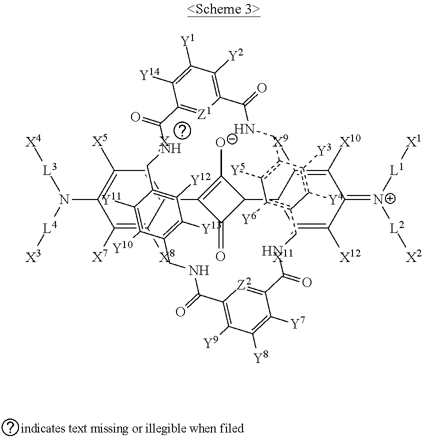

The chromophore-protecting group dye may be used alone as a red or green dye or may be used in combination with a toning dye, a quantum dot, or a pigment.

Examples of the toning dye may include triarylmethane-based dyes, anthraquinone-based dyes, benzylidene-based dyes, cyanine-based dyes, phthalocyanine-based dyes, azapophyrin-based dyes, indigo-based dyes, xanthene-based dyes, pyridone-azo-based dyes, etc.

The photosensitive composition may include 0.1 wt % to 50 wt % of the chromophore-protecting dye based on the solid content excluding a solvent. For example, the chromophore-protecting dye may be included in an amount of 0.1 wt % to 40 wt %, and preferably 0.5 wt % to 30 wt %. When the chromophore-protecting group dye is used within the above range, high luminance and contrast ratio can be expressed in a desired color coordinate.

### (5) Quantum Dots

Additionally, the chromophore-protecting group dye may be used in combination with quantum dots.

A quantum dot may have a core/shell structure consisting of a multilayer structure including a core and a shell surrounding the core. Additionally, a quantum dot may have a core/multishell structure having two or more shells. For example, a quantum dot may have a core/shell/shell structure having a core and a double shell.

The core and the shell of a quantum dot may consist of a group II-VI compound, a group II-V compound, a group III-V compound, a group III-IV compound, a group III-VI compound, a group IV-VI compound, a group III-VI compound, a group I-III-VI compound, or a mixture thereof, and a dopant may be doped or alloyed in the core or shell of the quantum dot, and a compound constituting the core and a compound constituting the shell may be different from each other.

The core may include one or more ternary compounds selected from InZnN, InZnP, InZnAs, InZnSb, InZnBi, GaZnN, GaZnP, GaZnAs, GaZnSb, GaZnBi, AlZnN, AlZnP, AlZnAs, AlZnSb, AlZnTi, CuGaS, and AgGaS.

Additionally, the core may include one or more quaternary element compounds selected from InGaZnN, InGaZnP, InGaZnAs, InGaZnSb, InGaZnBi, InAlZnN, InAlZnP, InAlZnAs, InAlZnSb, InAlZnBi, GaAlZnN, GaAlZnP, GaAlZnAs, GaAlZnSb, GaAlZnBi, CuInGaS, and AgInGaS.

The shell may be one or more selected from CdS, CdSe, CdTe, ZnS, ZnSe, ZnTe, ZnSeS, PbS, PbSe, PbSeS, PbTe, GaAs, GaP, InP, InGaP, InZnP, InAs, CuS, InN, GaN, InGaN, AIP, AlAs, InAs, GaAs, GaSb, InSb, AlSb, HgS, HgTe, HgCdTe, ZnCdS, ZnCdSe, CdSeTe, CuInSe₂, CuInS₂, AgInS₂, SnTe, GaS, and AgGaS.

The core/shell or core/multishell may further include a cluster molecule as a seed. The cluster molecule is a compound that serves as a seed in the process of preparing the core/shell or core/multishell, and as the precursors of the compound constituting the core/shell or core/multishell grow on the cluster molecule, the core/shell or core/multishell may be formed.

The quantum dot may have a single layer rather than a multilayer structure (a core/shell structure) and may be consisting of, for example, only a group II-VI compound.

The particle size of the quantum dot is preferably in the range of 1 nm to 30 nm, and most preferably 5 nm to 15 nm.

Additionally, the quantum dot may further include a ligand. For example, an amine compound, a thiol compound, or a carboxylic acid compound having a C₆₋₃₀ alkyl group or alkenyl group, (poly)ethyleneoxy group, or aryl group may be included as a ligand. Examples of the amine compound having an alkyl group include hexadecylamine, octylamine, etc.

Other examples of the ligand may include phosphine compounds including trioctylphosphine, triphenolphosphine, t-butylphosphine, etc.; phosphine oxides such as trioctylphosphine oxide, etc.; pyridine, thiophene, etc.

The type of the ligand is not limited to those exemplified above.

The ligands of the core-shell-ligand complex can prevent core/shell or core/multishells neighboring to one another from being aggregated and quenched. The ligand binds to the core/shell or core/multishells and may have a hydrophobic property.

When the chromophore-protecting dye and the quantum dots are mixed and used, they may be mixed at a weight ratio of 1:9 to 9:1, and specifically, 3:7 to 7:3. When the chromophore-protecting dye and the quantum dots are mixed within the range of the above weight ratio, it is possible to have high luminance and contrast ratio while maintaining color characteristics.

### (6) Colorant

The chromophore-protecting group dye may be used in combination with acolorants.

In order to color the pattern, colorants such as pigments and dyes may be used independently or together, and both organic pigments and inorganic pigments may be used as the pigments.

The pigment includes a red pigment, a green pigment, a blue pigment, a yellow pigment, a black pigment, etc. The pigments may be used alone or in combination of two or more, and the examples are not limited thereto.

Examples of the red pigment include C.I. Pigment Red 254, C.I. Pigment Red 255, C.I. Pigment Red 264, C.I. Pigment Red 270, C.I. Pigment Red 272, C.I. Pigment Red 177, C.I. Pigment Red 89, etc.

Examples of the green pigment include halogen-substituted copper phthalocyanine pigments such as C.I. Pigment Green 36 and C.I. Pigment Green 7.

Examples of the blue pigment include copper phthalocyanine pigments such as C.I. Pigment Blue 15:6, C.I. Pigment Blue 15, C.I. Pigment Blue 15:1, C.I. Pigment Blue 15:2, C.I. Pigment Blue 15:3, C.I. Pigment Blue 15:4, C.I. Pigment Blue 15:5, C.I., and Pigment Blue 16.

Examples of the yellow pigment include isoindoline-based pigments such as C.I. Pigment Yellow 139; quinophthalone-based pigments such as C.I. Pigment Yellow 138; C.I. nickel complex pigments such as Pigment Yellow 150.

Examples of the black pigment may include benzofuranone black, lactam black, aniline black, perylene black, titanium black, carbon black, etc.

The pigment may be included in a photosensitive composition in the form of a dispersion. Such pigment dispersion may consist of the pigments, a dispersion solvent, a dispersant, a dispersion resin, etc.

As the dispersing solvent, ethylene glycol acetate, ethyl cellosolve, propylene glycol methyl ether acetate, ethyl lactate, polyethylene glycol, cyclohexanone, propylene glycol methyl ether, etc. may be used, and among these, propylene glycol methyl ether acetate may preferably be used.

The dispersant helps to uniformly disperse the pigments in the dispersion, and all of nonionic, anionic, and cationic dispersants may be used. Specifically, polyalkylene glycol or an ester thereof, polyoxyalkylene, a polyhydric alcohol ester alkylene oxide adduct, an alcohol alkylene oxide adduct, a sulfonic acid ester, a sulfonic acid salt, a carboxylic acid ester, a carboxylic acid salt, an alkyl amide alkylene oxide adduct, alkyl amine, etc. may be used, and these may be used alone or in combination of two or more.

As the dispersion resin, an acryl-based resin including a carboxyl group may be used, which may improve the stability of the pigment dispersion and improve the resolution of the pattern during the color filter formation process.

When the chromophore-protecting group dye and the pigment are mixed and used, these may be mixed in a weight ratio of 1:9 to 9:1, and specifically, 3:7 to 7:3. Additionally, when the chromophore-protecting group dye and the toning dye are mixed and used, these may be mixed in a weight ratio of 1:9 to 9:1, and specifically, 3:7 to 7:3, and when these are mixed in the above weight ratio range, the resultant can have high luminance and contrast ratio while maintaining color characteristics.

The photosensitive composition may include 0.1 wt % to 50 wt % of the sum of the chromophore-protecting group dye and the colorant based on the solid content excluding the solvent. For example, it may be included in an amount of 0.1 wt % to 40 wt %, and preferably 0.5 wt % to 30 wt %. When the chromophore-protecting group dye and the colorant are used within the above range, high luminance and contrast ratio can be expressed in a desired color coordinate.

### (7) Solvent

As the solvent, materials may be used which are compatible with the binder resin, the reactive unsaturated compound, the reactive dye, the pigment, and the initiator but do not react with these.

Examples of the solvent include alcohols (e.g., methanol, ethanol, etc.); ethers (e.g., dichloroethyl ether, n-butyl ether, diisoamyl ether, methylphenyl ether, tetrahydrofuran, etc.); glycol ethers (e.g., ethylene glycol monomethyl ether, ethylene glycol monoethyl ether, etc.); cellosolve acetates (e.g., methyl cellosolve acetate, ethyl cellosolve acetate, diethyl cellosolve acetate, etc.); carbitols (e.g., methylethyl carbitol, diethyl carbitol, diethylene glycol monomethyl ether, diethylene glycol monoethyl ether, diethylene glycol dimethyl ether, diethylene glycol methyl ethyl ether, diethylene glycol diethyl ether, etc.); propylene glycol alkyl ether acetates (e.g., propylene glycol methyl ether acetate, propylene glycol propyl ether acetate, etc.); aromatic hydrocarbons (e.g., toluene, xylene, etc.); ketones (e.g., methyl ethyl ketone, cyclohexanone, 4-hydroxy-4-methyl-2-pentanone, methyl-n-propyl ketone, methyl-n-butyl ketone, methyl-n-amyl ketone, 2-heptanone, etc.); saturated aliphatic monocarboxylic acid alkyl esters (e.g., ethyl acetate, n-butyl acetate, isobutyl acetate, etc.); lactic acid esters (e.g., methyl lactate, ethyl lactate, etc.); oxyacetic acid alkyl esters (e.g., methyloxyacetate, ethyloxyacetate, butyl oxyacetate, etc.); alkoxy acetate alkyl esters (e.g., methoxy methyl acetate, methoxy ethyl acetate, methoxy butyl acetate, ethoxy methyl acetate, ethoxy ethyl acetate, etc.); 3-oxypropionic acid alkyl esters (e.g., 3-oxy methyl propionate, 3-oxy ethyl propionate, etc.); 3-alkoxy propionic acid alkyl esters (e.g., 3-methoxy methyl propionate, 3-methoxy ethyl propionate, 3-ethoxy ethyl propionate, 3-ethoxy methyl propionate, etc.); 2-oxypropionic acid alkyl esters (e.g., methyl 2-oxypropionate, ethyl 2-oxypropionate, propyl 2-oxypropionate, etc.); 2-alkoxy propionic acid alkyl esters (e.g., 2-methoxy methyl propionate, 2-methoxy ethyl propionate, 2-ethoxy ethyl propionate, 2-ethoxy methyl propionate, etc.); 2-oxy-2-methyl propionic acid esters (e.g., 2-oxy-2-methyl methyl propionate, 2-oxy-2-methyl ethyl propionate, etc.); monooxy monocarboxylic acid alkyl esters of 2-alkoxy-2-methyl propionic acid alkyls (e.g., 2-methoxy-2-methyl methyl propionate, 2-ethoxy-2-methyl ethyl propionate, etc.); esters (e.g., 2-hydroxyethyl propionate, 2-hydroxy-2-methyl ethyl propionate, ethyl hydroxyacetate, 2-hydroxy-3-methyl methyl butanoate, etc.); ketonic acid esters (e.g., ethyl pyruvate, etc.), etc.

Further, high boiling point solvents such as N-methylformamide, N,N-dimethylformamide, N-methylformanilad, N-methylacetamide, N,N-dimethylacetamide, N-methylpyrrolidone, dimethyl sulfoxide, benzylethyl ether, dihexyl ether, acetylacetone, isophorone, caproic acid, caprylic acid, 1-octanol, 1-nonanol, benzyl alcohol, benzyl acetate, ethyl benzoate, diethyl oxalate, diethyl maleate, γ-butyrolactone, ethylene carbonate, propylene carbonate, and phenyl cellosolve acetate may also be used.

Among the solvents above, considering compatibility and reactivity, the following solvents may be used: glycol ethers (e.g., ethylene glycol monoethyl ether, etc.); ethylene glycol alkyl ether acetates (e.g., ethyl cellosolve acetate, etc.); esters (e.g., ethyl 2-hydroxypropionate, etc.); carbitols (e.g., diethylene glycol monomethyl ether, etc.); and propylene glycol alkyl ether acetates (e.g., propylene glycol methyl ether acetate, propylene glycol propyl ether acetate, etc.).

The solvent may be included as a balance based on the total amount of the photosensitive resin composition, and specifically in an amount of 50 wt % to 90 wt %. When the solvent is included within the above range, the photosensitive resin composition has an appropriate viscosity, and thus the processability becomes excellent in preparing the pattern layer.

### (8) Other Additives

In order to prevent stains or spots during application, to improve leveling performance, and to prevent the generation of undeveloped residues, the photosensitive composition may further include other additives such as malonic acid; 3-amino-1,2-propanediol; a silane-based coupling agent including a vinyl group or (meth)acryloxy group; a leveling agent; a fluorine-based surfactant; and a radical polymerization initiator.

Additionally, the photosensitive composition may further include an additive such as an epoxy compound so as to improve adhesion, etc. with a substrate.

Examples of the epoxy compound may include a phenol novolac epoxy compound, a tetramethyl biphenyl epoxy compound, a bisphenol A type epoxy compound, an alicyclic epoxy compound, or a combination thereof.

The content of the additives can easily be adjusted according to desired physical properties.

Still another embodiment of the present disclosure may provide a color filter prepared using the photosensitive composition described above. A method of preparing the color filter is as follows.

### <Color Filter Formation Process>

On a glass substrate on which nothing is coated, or on a glass substrate on which a protective film, SiN_{X}, is applied in a thickness of 500 Å to 1500 Å, the above-described photosensitive resin composition is applied using an appropriate method (e.g., spin coating, slit coating, etc.) to form a thickness of 3.1 μm to 3.4 μm, respectively. After the application, light is irradiated to form a pattern required for a color filter. After the light irradiation, when the coating layer is treated with an alkaline developing solution, the non-irradiated portion of the coating layer is dissolved and a pattern required for the color filter is formed. By repeating this process according to the required number of R, G, and B colors, a color filter having a desired pattern can be obtained. In the above process, crack resistance, solvent resistance, etc. can be further improved by heating again the image pattern obtained by development or curing by irradiation with actinic rays, etc.

Still another embodiment of the present disclosure may provide an organic light emitting display device.

Hereinafter, an organic light emitting display device will be described referring to the FIGURE. The organic light emitting display device according to an embodiment of the present disclosure is characterized in that it includes a substrate (1), a TFT layer (2) on the substrate, a flattening layer (3) on the TFT layer, an organic light emitting device layer on the flattening layer, a sealing layer (8) disposed on the organic light emitting device layer, a touch panel (9) disposed on the sealing layer, and a color filter disposed on the touch panel, in which the color filter includes a pattern or film formed of the photosensitive composition of the present disclosure.

The pattern or film is formed of a photosensitive composition including, as essential component, the chromophore-protecting group dye, which includes a chromophore including the structure represented Formula (4) above and a protecting group including the structure represented by Formula (5) above.

The substrate (1) may be a flexible substrate. The substrate may be made of a plastic material having excellent heat resistance and durability, such as polyimide (PI), polyethylene terephthalate (PET), polyethylene naphtalate (PEN), polycarbonate (PC), polyarylate (PAR), polyetherimide (PEI), and polyethersulfone (PES). However, the present disclosure is not limited thereto, and various flexible materials (e.g., metal foil or thin glass) may be used. Meanwhile, the substrate may be a rigid a substrate, and in particular, the substrate may be made of a glass material containing SiO₂ as a main component.

In the case of a bottom emission type in which the image is implemented in the direction of a substrate, the substrate must be formed of a transparent material. However, in the case of a top emission type in which the image is implemented in the opposite direction of a substrate, the substrate does not necessarily have to be formed of a transparent material. In this case, the substrate may be formed of a metal. When the substrate is formed of a metal, the substrate may include one or more selected from the group consisting of carbon, iron, chromium, manganese, nickel, titanium, molybdenum, and stainless steel (SUS), but is not limited thereto.

A TFT layer (2) may be disposed on the substrate. As used herein, the term TFT layer collectively refers to a thin film transistor (TFT) array for operating an organic light emitting device, and it refers to a driving part for displaying an image. The FIGURE shows only an organic light emitting device and a driving thin film transistor for driving the organic light emitting device, which are only for convenience of description and the present disclosure is not limited to what is shown, and it is apparent to those skilled in the art that a plurality of thin film transistors, storage capacitors, and various wirings may be further included.

The TFT layer may be protected by being covered with a flattening layer (3). The flattening layer may include an inorganic insulating layer and/or an organic insulating layer. Examples of the inorganic insulating film that can be used for the flattening layer may include silicon oxide (SiO₂), silicon nitride (SiNₓ), silicon oxynitride (SiON), aluminum oxide (Al₂O₃), titanium oxide (TiO₂), tantalum oxide (Ta₂Os), hafnium oxide (HfO₂), zirconium oxide (ZrO₂), barium strontium titanate (BST), lead zirconate-titanate (PZT), etc.

Additionally, examples of the organic insulating film that can be used for the flattening layer may include common general-purpose polymers (PMMA, PS), polymer derivatives having phenolic groups, acryl-based polymers, imide-based polymers, arylether-based polymers, amide-based polymers, fluorine-based polymers, p-xylene-based polymers, vinyl alcohol-based polymers, and blends thereof.

Meanwhile, the flattening layer may have a composite stacked structure of an inorganic insulating film and an organic insulating film.

An organic light emitting device layer may be formed on the upper part of the flattening layer. The organic light emitting device layer may include a pixel electrode (4) formed on the flattening layer, a counter electrode (7) disposed to face the pixel electrode, and an organic material layer (6) interposed therebetween. When a voltage is applied between the pixel electrode and the counter electrode, the organic material layer can emit light. The organic material layer may emit red light, green light, blue light, white light, etc. The organic light emitting display device may further include blue, green, and red color filters so as to express color images when the organic material layer emits white light, and so as to increase color purity and light efficiency when the organic material layer emits red light, green light, and blue light.

The organic light emitting display device may be classified into a bottom emission type, a top emission type, a dual emission type, etc. according to the emission direction. In an organic light emitting display device of the bottom emission type, the pixel electrode is provided as a light transmitting electrode and the counter electrode is provided as a reflective electrode. In an organic light emitting display device of the top emission type, the pixel electrode is provided as a reflective electrode and the counter electrode is provided as a semi-transmissive electrode. In the present disclosure, the top emission type, in which the organic light emitting device emits light in the direction of a sealing layer, will be described.

The pixel electrode may be a reflective electrode. The pixel electrode may include a stacked structure of a reflective layer and a transparent or semi-transparent electrode layer having a high work function. The reflective layer may include Ag, Mg, Al, Pt, Pd, Au, Ni, Nd, Ir, Cr, or an alloy thereof. The transparent or semi-transparent electrode layer may include at least one material selected from among transparent conductive oxide materials, such as indium tin oxide (ITO), indium zinc oxide (IZO), zinc oxide (ZnO), indium oxide (In₂O₃; indium oxide), indium gallium oxide (IGO), aluminum zinc oxide (AZO), etc. The pixel electrode may be formed by patterning in an island shape corresponding to each pixel. Additionally, the pixel electrode may function as an anode electrode.

Meanwhile, a pixel defining layer (5) may be disposed on the pixel electrode so as to cover the edge of the pixel electrode and include a predetermined opening part that exposes the central part of the pixel electrode. An organic material layer including an organic light emitting layer that emits light may be disposed on the area limited by the opening part. The region on which an organic material layer is disposed may be defined as a light emitting region.

Meanwhile, when the light emitting region is formed within the opening part of the pixel defining layer, a region protruding by the pixel defining layer is disposed between the light emitting regions, and this region may be defined as a non-light emitting area because an organic light emitting layer is not formed in this protruding area.

The counter electrode may be formed as a transmissive electrode. The counter electrode may be a semi-transmissive layer in which a metal having a small work function (e.g., Li, Ca, LiF/Ca, LiF/Al, Al, Mg, Ag, etc.) is thinly formed. In order to compensate for the high resistance problem of the thin metal semi-transmissive layer, a transparent conductive layer made of a transparent conductive oxide may be stacked on the metal semi-transmissive layer. The counter electrode may be formed over the entire surface of a substrate in the form of a common electrode. Additionally, such a counter electrode may function as a cathode electrode.

The polarities of the pixel electrode and the counter electrode as described above may be opposite to each other.

The organic material layer includes an organic light emitting layer that emits light, and the organic light emitting layer may use a low molecular weight organic material or high molecular weight organic material. When the organic light emitting layer is a low molecular-weight organic layer formed of a low molecular organic material, a hole transport layer (HTL), a hole injection layer (HIL), etc. may be disposed in the direction of the pixel electrode around the organic light emitting layer, whereas an electron transport layer (ETL), an electron injection layer (EIL), etc. may be disposed in the direction of a counter electrode. Certainly, functional layers other than the hole injection layer, hole transport layer, electron transport layer, and electron injection layer may be stacked.

A sealing layer (8) may be disposed on the organic light emitting device layer so as to cover the organic light emitting device layer. The organic light emitting device included in the organic light emitting device layer is composed of an organic material and thus can easily be deteriorated by external moisture or oxygen. Therefore, in order to protect the organic light emitting device, the organic light emitting device layer must be sealed. The sealing layer is a means for sealing the organic light emitting device layer, and may have a structure in which a plurality of inorganic layers and a plurality of organic layers are alternately stacked.

As for the organic light emitting display device according to this embodiment, it is preferable to form a sealing layer with a thin film in which a plurality of inorganic films and a plurality of organic films are alternately stacked instead of a sealing substrate, and flexibility and thinning of the organic light emitting display device can easily be realized by using a thin film as a sealing means.

The sealing layer may include a plurality of inorganic layers and a plurality of organic layers. The inorganic layers and the organic layers may be alternately stacked on each other.

The inorganic layers may be formed of a metal oxide, a metal nitride, a metal carbide, or a combination thereof. For example, the inorganic layers may be made of aluminum oxide, silicon oxide, or silicon nitride. According to another embodiment, the inorganic layers may include a stacked structure of a plurality of inorganic insulating layers. The inorganic layers may perform the functions of preventing the penetration of external moisture and/or oxygen, etc. into the organic light emitting device layer.

The organic layers may be high molecular weight organic compounds. For example, the organic layers may include any one of epoxy, acrylate, and urethane acrylate. The organic layers may perform the functions of relieving internal stress of the inorganic layers or compensating for defects and flattening the inorganic layers.

The order of stacking the inorganic and organic layers constituting the sealing layer is not limited. An organic or inorganic layer may be stacked on the organic light emitting device layer, and the uppermost layer of the sealing layer may be an organic or inorganic layer.

A touch panel (9) may be formed on the sealing layer. The touch panel may include a first touch electrode formed on the sealing layer, a second touch electrode disposed to face the first touch electrode, and an insulating layer interposed therebetween.

The first touch electrode and the second touch electrode may be formed in a grid pattern or specific pattern shape. The first touch electrode may be formed to be in contact with an upper part of the sealing layer, and an inorganic layer may be additionally provided between the sealing layer and the first touch electrode.

The first touch electrode and the second touch electrode may be formed of indium tin oxide (ITO) or of a metal mesh and may preferably be formed of a metal mesh.

The metal mesh is an electrode prepared by printing an opaque metal (copper, silver, gold, aluminum, etc.) in the form of a grid with a thickness of 1 μm to 7 μm. Due to the use of a metal with high conductivity, the metal mesh has the advantages in that it has a low resistance value thus having a fast touch response speed, enables easy realization of a large screen, and is cheaper than ITO film in cost. In addition, the metal mesh electrode has excellent durability against repeated bending compared to the ITO electrode, thus being suitable for use as a touch panel electrode for a foldable display.

The touch panel is preferably a capacitive type touch panel that detects the position by recognizing the part where the amount of current has changed and calculating the size using the capacitance of the human body when the user touches the touch panel.

It should be apparent to those skilled in the art that the organic light emitting display device of the present disclosure is not limited to those illustrated, and Control IC (which converts the analog signal transmitted from the touch panel into a digital signal and controls the coordinate values, etc. needed to determine the coordinates of the touch area), optical clear adhesive, a flexible printed circuit board (FPCB), in which conductive and signal line patterns are formed to thereby transmit various signals to electronic components, etc., and other various kinds of electronic components and various kinds of wirings may be further included.

A color filter may be formed on the touch panel. The color filter may be prepared in advance and provided in an organic light emitting display device, or a process of forming the color filter directly on a touch panel may be performed.

The color filter may be positioned on an upper part of the touch panel, and it may include a color unit (10), which is aligned in a vertical direction with reference to the light emitting area of the organic light emitting device layer; and a color separation unit (11), which is vertically aligned with the non-emission area and separates the color unit.

The photosensitive composition of the present disclosure may be included in the color separation unit and narrow the wavelength range of the light emitted from the light emitting region, thereby improving the color purity of the organic light emitting display device.

Additionally, the photosensitive composition of the present disclosure may be included in the color separation unit and absorb and block external light incident to the organic light emitting display device thereby improving outdoor visibility.

The photosensitive composition of the present disclosure may include the chromophore-protecting group dye alone or may include the chromophore-protecting group dye together with a red dye or a red pigment to thereby form a red color portion vertically aligned with a red light emitting region.

The photosensitive composition of the present disclosure may include the chromophore-protecting group dye alone or may include the chromophore-protecting group dye together with a green dye or a green pigment to thereby form a green color portion vertically aligned with a green light emitting region.

The photosensitive composition of the present disclosure may include the chromophore-protecting group dye alone or may include the chromophore-protecting group dye together with a blue dye or a blue pigment to thereby form a blue color portion vertically aligned with a blue light emitting region.

The photosensitive composition of the present disclosure may include the chromophore-protecting group dye alone or may include the chromophore-protecting group dye together with a black dye or a black pigment to thereby form a black color portion vertically aligned with a black light emitting region, in which as the black pigment, carbon black is preferred.

In the case of forming a color part of a color filter, particularly a red color part or green color part, using the photosensitive composition of the present disclosure, the resulting color purity is excellent and light resistance to sunlight is also improved, and thus is very preferable. Additionally, when the color separation part of the color filter is formed using the photosensitive composition of the present disclosure, not only light resistance to sunlight can be secured, but also chemical resistance essential to the solution process can be secured, and thus is very preferable.

When the color part or the color separation part of the color filter is formed using the photosensitive composition of the present disclosure, it has a low amount of outgas generation and can form a pattern of a fine size, so that a high resolution color filter can be prepared.

Additionally, the photocuring of the photosensitive composition of the present disclosure sufficiently proceeds in the process of exposure to light during the photo-patterning process and the post-baking treatment process proceeds at 100° C. or lower; therefore, the color filter forming process can be performed without causing heat damage to the organic layer of the organic light emitting device layer.

The position of each layer in the structure of the above-described organic light emitting display device is not limited, and it is apparent to those skilled in the art that several functional layers having specific purposes and functions may be further disposed between each layer, and the organic light emitting display device of the present disclosure is not limited to the structure and drawings described above.

Hereinafter, synthesis examples and examples according to the present disclosure will be described in detail, but the synthesis examples and examples of the present disclosure are not limited thereto.

### Synthesis Example 1

### (Preparation of Compound 1-1)

20 g of 9,9′-bisphenol fluorene (Sigma Aldrich), 8.67 g of glycidyl chloride (Sigma Aldrich), 30 g of anhydrous potassium carbonate, and 100 mL of dimethylformamide were added into a 300 mL 3-neck round-bottom flask equipped with a distillation tube, and the temperature was raised to 80° C. and reacted for 4 hours. Then, the temperature was lowered to 25° C. and the reaction solution was filtered and the filtrate was added dropwise to 1,000 mL of water while stirring, and the precipitated powder was filtered, washed with water, and dried under reduced pressure at 40° C. to obtain 25 g of Compound 1-1. The obtained powder was subjected to purity analysis by HPLC and was shown to have a purity of 98%.

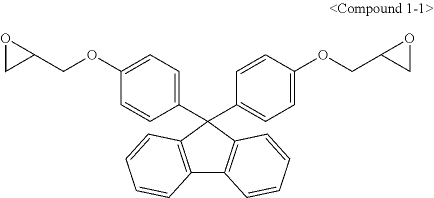 [SMILES: c1ccc2c(c1)-c1ccccc1C2(c1ccc(OCC2CO2)cc1)c1ccc(OCC2CO2)cc1]

### Synthesis Example 2

### (Preparation of Compounds 2-1 to 2-3)

Compound 1-1 obtained in Synthesis Example 1, 8 g of acrylic acid (Daejung Chemicals & Metals), 0.2 g of benzyltriethylammonium chloride (Daejung Chemicals & Metals), 0.2 g of hydroquinone (Daejung Chemicals & Metals), and 52 g of toluene (Sigma Aldrich) were added into a 300 mL 3-neck round-bottom flask equipped with a distillation tube, and the mixture was stirred at 110° C. for 6 hours. After completion of the reaction, toluene was removed by distillation under reduced pressure to obtain a product. After a glass column (diameter: 220 mm) was filled with 500 g of silica gel 60 (230-400 mesh, Merck), 20 g of the product was loaded thereinto, and separation was performed using 10 L of a solvent in which hexane and ethyl acetate were mixed in a 4:1 volume ratio and thereby Compounds 2-1 to 2-3 were separated.

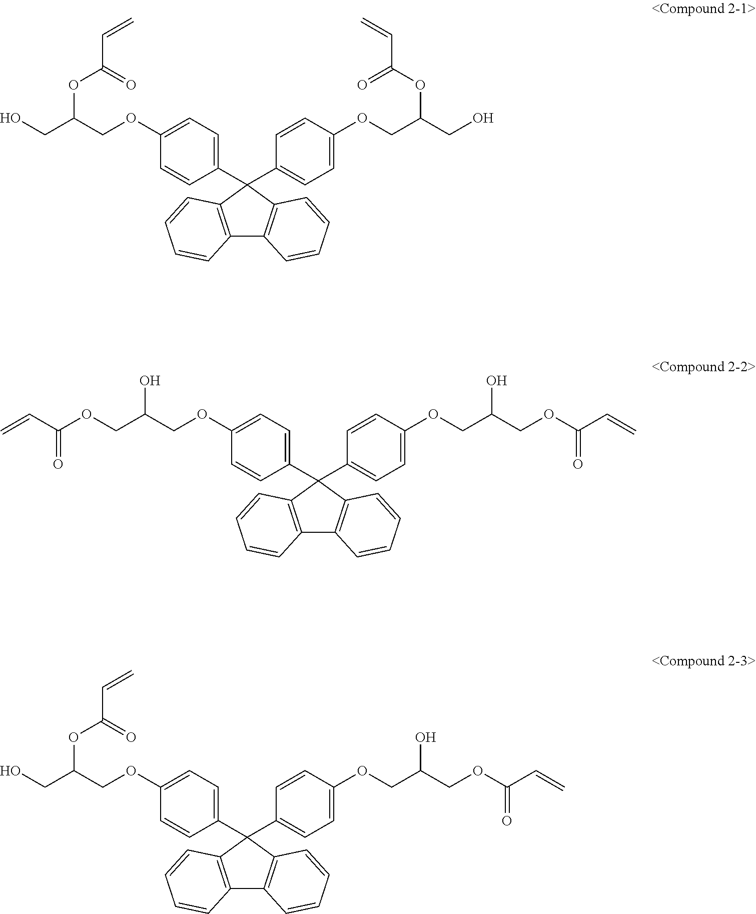 [SMILES: C=CC(=O)OC(CO)COc1ccc(C2(c3ccc(OCC(CO)OC(=O)C=C)cc3)c3ccccc3-c3ccccc32)cc1 ; C=CC(=O)OCC(O)COc1ccc(C2(c3ccc(OCC(O)COC(=O)C=C)cc3)c3ccccc3-c3ccccc32)cc1 ; C=CC(=O)OCC(O)COc1ccc(C2(c3ccc(OCC(CO)OC(=O)C=C)cc3)c3ccccc3-c3ccccc32)cc1]

### Synthesis Example 3 to 9

### (Preparation of Polymers 1-1 to 1-7)

Compound 1-1, Compound 1-2, and Compound 1-3 obtained in Synthesis Example 2-2 were added, in amounts into a 50 mL 3-neck round-bottom flask equipped with a distillation tube as shown in Table 1 below, and then, 0.1 g of tetraethyl ammonium bromide (Daejung Chemicals & Metals), 0.03 g of hydroquinone (Daejung Chemicals & Metals), and 8.05 g of propylene glycol methyl ether acetate (Sigma Aldrich) were added into a 50 mL 3-neck round-bottom flask equipped with a distillation tube, and 1.22 g of biphenyltetracarboxylic acid dianhydride (Mitsubishi Gas) and 0.38 g of tetrahydrophthalic acid (Sigma Aldrich) were additionally added thereto and the mixture was stirred at 110° C. for 6 hours. After completion of the reaction, the reaction solution was recovered to obtain Polymers 1-1 to 1-7, in which the repeating units with the structures of Compounds 2-1, 2-2, and 2-3 were mixed, in the form of a solution containing 45% solids. The synthesized polymers were analyzed for their weight average molecular weight (Mw) using gel permeation chromatography (Agilent).

TABLE 1

| | Synthesis | Synthesis | Synthesis | Synthesis | | Synthesis | | Synthesis | Synthesis |
|---|---|---|---|---|---|---|---|---|---|
| | Example 3 | Example 4 | Example 5 | Example 6 | | Example 7 | | Example 8 | Example 9 |
| | (Polymer | (Polymer | (Polymer | (Polymer | | (Polymer | | (Polymer | (Polymer |
| | 1-1) | 1-2) | 1-3) | 1-4) | | 1-5) | | 1-6) | 1-7) |
| Compound | 3 g | 1 g | 1 g | 4.25 | g | 0.25 | g | 5 g | 0 g |
| 2-1 | | | | | | | | | |
| Compound | 1 g | 3 g | 1 g | 0.25 | g | 4.25 | g | 0 g | 5 g |
| 2-2 | | | | | | | | | |
| Compound | 1 g | 1 g | 3 g | 0.5 | g | 0.5 | g | 0 g | 0 g |
| 2-3 | | | | | | | | | |

| | | | | | | | |
|---|---|---|---|---|---|---|---|
| Weight | 4,800 | 4,200 | 4,600 | 4,400 | 4,100 | 5,200 | 3,300 |
| Average | g/mol | g/mol | g/mol | g/mol | g/mol | g/mol | g/mol |
| Molecular | | | | | | | |
| Weight | | | | | | | |

### Synthesis Example 10

### (Preparation of Compound 3-1)

20 g (0.147 mol) of trichloro silane (Gelest) and 17.51 g (0.147 mol) of 6-chloro-1-hexene (Aldrich) were dissolved in 200 mL of ethyl acetate in a 3-neck round-bottom flask equipped with a distillation tube to which cooling water was connected, and then 0.02 g of a platinum (0)-1,3-divinyl-1,1,3,3-tetramethyldisiloxane complex solution (2 wt % in xylene/Aldrich) was added, and the temperature was raised to 75° C. while adding nitrogen thereto and the mixture was allowed to react for 5 hours, and the solution was filtered with a 0.1 μm Teflon membrane to remove the platinum catalyst. Thereafter, 15.6 g (0.487 mol) of methanol was added dropwise at room temperature for 30 minutes, and the temperature was again raised to 50° C. and the mixture was allowed to react for additional 2 hours, and the reaction solution was distilled under reduced pressure to remove the solvent. 24 g (0.1 mol) of the thus-obtained 6-chlorohexyltrimethoxysilane, 8 g (0.15 mol) of sodium methoxide (Aldrich), and 187 mL (0.15 mol) of a hydrogen sulfide THF solution (0.8 M concentration), and 100 mL of methanol were added into an autoclave, and the mixture was allowed to react at 100° C. for 2 hours. After cooling the reaction solution, 100 mL of hydrogen chloride in methanol (1.25 M concentration) was added thereto dropwise at room temperature for 30 minutes, the resulting salt was filtered off, and then distilled under reduced pressure to obtain Compound 3-1 (23 g).

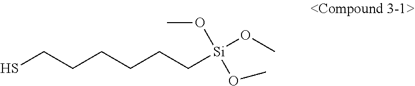

### Synthesis Example 11

### (Preparation of Compound 3-2)

The synthesis was performed in the same manner as in Synthesis Example 10 above, except that 23.7 g (0.147 mol) of 9-chloro-1-nonene (AK Scientific) was used instead of 6-chloro-1-hexene, and thereby 24 g of Compound 3-2 was obtained.

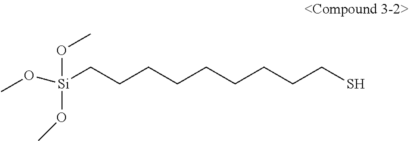 [SMILES: CO[Si](CCCCCCCCCS)(OC)OC]

### Synthesis Example 12

### (Preparation of Compound 3-3)

The synthesis was performed in the same manner as in Synthesis Example 10, except that 30 g (0.147 mol) of 12-chloro-1-dodecene (Atomax Chemicals) was used instead of 6-chloro-1-hexene, and thereby 26 g of Compound 3-3 was obtained.

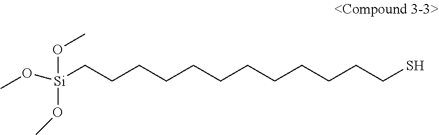 [SMILES: CO[Si](CCCCCCCCCCCCS)(OC)OC]

### Synthesis Example 13

### (Preparation of Compound 3-4)

The synthesis was performed in the same manner as in Synthesis Example 10, except that 22.4 g (0.487 mol) of ethanol (Aldrich) was used instead of methanol which was added after removing platinum, and thereby 24 g of Compound 3-4 was obtained.

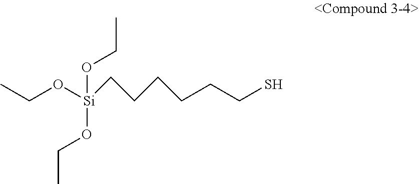 [SMILES: CCO[Si](CCCCCCS)(OCC)OCC]

### Synthesis Example 14

### (Preparation of Compound 3-5)

The synthesis was performed in the same manner as in Synthesis Example 10, except that 36 g (0.487 mol) of 1-butanol (Aldrich) was used instead of methanol which was added after removing platinum, and thereby 27 g of Compound 3-5 was obtained.

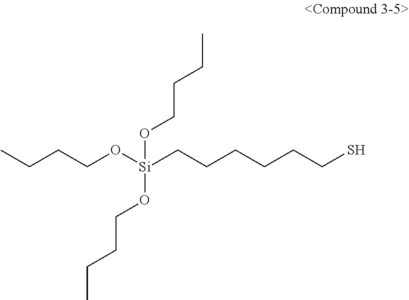 [SMILES: CCCCO[Si](CCCCCCS)(OCCCC)OCCCC]

### Synthesis Example 15

### (Preparation of Compound 3-6)

The synthesis was performed in the same manner as in Synthesis Example 10, except that 18 g (0.147 mol) of dichloromethylsilane was used instead of trichlorosilane, and thereby 22 g of Compound 3-6 was obtained.

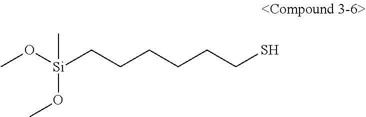

### Synthesis Example 16

### (Preparation of Polymer 2-1)

6.36 g (34 mmol) of KBM 803 [3-(trimethoxysilyl)-1-propanethiol] (Shinetsu), which is the same as Compound 3-7, was added to 360 g of the solution of Polymer 1-1 prepared in Synthesis Example 3, and the temperature was raised to 60° C. and the mixture was stirred for 4 hours to obtain Polymer 2-1, which is a cardo-based binder resin the same as Compound 3-7 where a silane group is substituted.

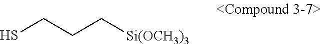

### Synthesis Examples 17 to 22

### (Preparation of Polymers 2-2 to 2-7)

Polymers 2-2 to 2-7, which are cardo-based binder resins where a silane group is substituted, were prepared in the same manner as in Synthesis Example 16, except that Polymers 1-2 to 1-7 described in Table 2 below were used instead of the solution of Polymer 1-1.

The weight average molecular weights of Polymers 2-1 to 2-7 synthesized in Synthesis Examples 16 to 22 are shown in Table 2 below.

TABLE 2

| | Synthesis | Synthesis | Synthesis | Synthesis | Synthesis | Synthesis | Synthesis |
|---|---|---|---|---|---|---|---|
| | Example | Example | Example | Example | Example | Example | Example |
| | 16 | 17 | 18 | 19 | 20 | 21 | 22 |
| | (Polymer | (Polymer | (Polymer | (Polymer | (Polymer | (Polymer | (Polymer |
| | 2-1) | 2-2) | 2-3) | 2-4) | 2-5) | 2-6) | 2-7) |
| Polymer | Polymer 1-1 | Polymer 1-2 | Polymer 1-3 | Polymer 1-4 | Polymer 1-5 | Polymer 1-6 | Polymer 1-7 |
| Backbone | | | | | | | |
| Silane Group | Compound | Compound | Compound | Compound | Compound | Compound | Compound |
| | 3-7 | 3-7 | 3-7 | 3-7 | 3-7 | 3-7 | 3-7 |
| Weight | 4,880 | 4,250 | 4,680 | 4,430 | 4,140 | 5,270 | 3,320 |
| Average | g/mol | g/mol | g/mol | g/mol | g/mol | g/mol | g/mol |
| Molecular | | | | | | | |
| Weight | | | | | | | |

### Synthesis Example 23

### (Preparation of Polymer 3-1)

8.1 g (34 mmol) of 6-(trimethoxysilyl)-1-hexanethiol (Compound 3-1) was added to 360 g of the solution of Polymer 1-1 prepared in Synthesis Example 3, and the temperature was raised to 60° C., and the mixture was stirred for 4 hours to obtain Polymer 3-1, which is a cardo-based binder resin the same as Compound 3-1 where a silane group is substituted.

### Synthesis Examples 24 to 29

### (Preparation of Polymers 3-2 to Polymer 3-7)

Polymer 3-2 to 3-7, which are cardo-based binder resins where a silane group is substituted, were prepared in the same manner as in Synthesis Example 23, except that Polymers 1-2 to 1-7 described in Table 3 below were used instead of the solution of Polymer 1-1.

The weight average molecular weights of Polymers 3-1 to 3-7 synthesized in Synthesis Examples 23 to 29 are shown in Table 3 below.

TABLE 3

| | Synthesis | Synthesis | Synthesis | Synthesis | Synthesis | Synthesis | Synthesis |
|---|---|---|---|---|---|---|---|
| | Example | Example | Example | Example | Example | Example | Example |
| | 23 | 24 | 25 | 26 | 27 | 28 | 29 |
| | (Polymer | (Polymer | (Polymer | (Polymer | (Polymer | (Polymer | (Polymer |
| | 3-1) | 3-2) | 3-3) | 3-4) | 3-5) | 3-6) | 3-7) |
| Polymer | Polymer 1-1 | Polymer 1-2 | Polymer 1-3 | Polymer 1-4 | Polymer 1-5 | Polymer 1-6 | Polymer 1-7 |
| backbone | | | | | | | |
| Silane Group | Compound | Compound | Compound | Compound | Compound | Compound | Compound |
| | 3-1 | 3-1 | 3-1 | 3-1 | 3-1 | 3-1 | 3-1 |
| Weight | 4,900 | 4,280 | 4,690 | 4,470 | 4,160 | 5,290 | 3,360 |
| Average | g/mol | g/mol | g/mol | g/mol | g/mol | g/mol | g/mol |
| Molecular | | | | | | | |
| Weight | | | | | | | |

### Synthesis Example 30

### (Preparation of Polymer 4-1)

9.53 g (34 mmol) of 6-(triethoxysilyl)-1-hexanethiol (Compound 3-4) was added to 360 g of the solution of Polymer 1-1 prepared in Synthesis Example 3, and the temperature was raised to 60° C., and the mixture was stirred for 4 hours to obtain Polymer 3-1, which is a cardo-based binder resin the same as Compound 3-4 where a silane group is substituted.

### Synthesis Example 31 to 36

### (Preparation of Polymers 4-2 to 4-7)

Polymers 4-2 to 4-7, which are cardo-based binder resins where a silane group is substituted, were prepared in the same manner as in Synthesis Example 30, except that Polymers 1-2 to 1-7 described in Table 4 below were used instead of the solution of Polymer 1-1.

The weight average molecular weights of Polymers 4-1 to 4-7 synthesized in Synthesis Examples 30 to 36 are shown in Table 4 below.

TABLE 4

| | Synthesis | Synthesis | Synthesis | Synthesis | Synthesis | Synthesis | Synthesis |
|---|---|---|---|---|---|---|---|
| | Example | Example | Example | Example | Example | Example | Example |
| | 30 | 31 | 32 | 33 | 34 | 35 | 36 |
| | (Polymer | (Polymer | (Polymer | (Polymer | (Polymer | (Polymer | (Polymer |
| | 4-1) | 4-2) | 4-3) | 4-4) | 4-5) | 4-6) | 4-7) |
| Polymer | Polymer 1-1 | Polymer 1-2 | Polymer 1-3 | Polymer 1-4 | Polymer 1-5 | Polymer 1-6 | Polymer 1-7 |
| backbone | | | | | | | |
| Silane Group | Compound | Compound | Compound | Compound | Compound | Compound | Compound |
| | 3-4 | 3-4 | 3-4 | 3-4 | 3-4 | 3-4 | 3-4 |
| Weight | 4,900 | 4,290 | 4,690 | 4,480 | 4,180 | 5,290 | 3,380 |
| Average | g/mol | g/mol | g/mol | g/mol | g/mol | g/mol | g/mol |
| Molecular | | | | | | | |
| Weight | | | | | | | |

### Synthesis Example 37

### (Preparation of Compound 4-1)

20 g of pentaerythritol (Sigma Aldrich) and 42.77 g of acrylic acid (Sigma Aldrich) were added along with 100 g of toluene into a 300 mL 3-neck round-bottom flask equipped with a distillation tube and a Dean-Stark tube, and then 1 g of sulfuric acid was added thereto, and the temperature was raised to 110° C. and allowed to react for 8 hours. Then, the temperature was lowered to 25° C. and the reaction solution was washed 3 times with 200 mL of an aqueous solution of 10 wt % Na₂CO₃, washed once with 200 ml of water, and then the organic solution of the upper layer was washed was dried at 40° C. under reduced pressure to obtain Compound 4-1 (50 g).

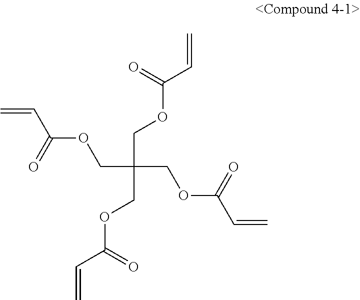 [SMILES: C=CC(=O)OCC(COC(=O)C=C)(COC(=O)C=C)COC(=O)C=C]

### Synthesis Example 38

### (Preparation of Compound 5-1)

10 g of 1-methoxynaphthalene (TCI) and 12.7 g of 3-oxo-3-phenylpropanoyl chloride were added along with 120 mL of dichloro ethane into a 300 mL 3-neck round-bottom flask in an N₂ atmosphere, dissolved by stirring, and then cooled to 5° C. After adding 9.27 g of aluminum chloride (Aldrich) dropwise thereto for 30 minutes, the mixture was stirred for 1 hour, the temperature was raised to room temperature, and the mixture was stirred for 2 hours. After adding 100 mL of an aqueous 1 N HCl solution to the reaction solution and stirring, the organic layer was collected, washed 3 times with 100 mL of distilled water, distilled under reduced pressure, and separated using a silica gel column to obtain 13.4 g of Compound 5-1.

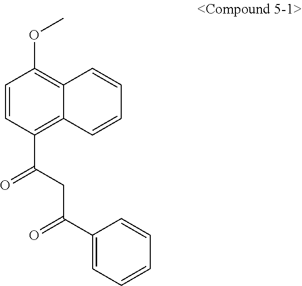 [SMILES: COc1ccc(C(=O)CC(=O)c2ccccc2)c2ccccc12]

### Synthesis Example 39

### (Preparation of Compound 5-2)

10 g of Compound 5-1 obtained in Synthesis Example 38 and 27.8 g of N,N-dimethylformamide (Aldrich) were added into a 100 mL 3-neck round-bottom flask in an N₂ atmosphere and dissolved, cooled to 5° C., and then, 5.5 g of an aqueous solution of 35 wt % HCl g and 8 g of isobutyl acetate (Aldrich) were added dropwise to the reactor for 30 minutes and allowed to react for 10 hours. After the reaction, the resultant was washed 5 times with 100 mL of distilled water, distilled under reduced pressure, and separated using a silica gel column to obtain 5.48 g of Compound 5-2.

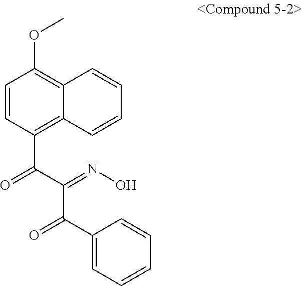 [SMILES: COc1ccc(C(=O)/C(=N/O)C(=O)c2ccccc2)c2ccccc12]

### Synthesis Example 40

### (Preparation of Compound 5-3)

5 g of Compound 5-2 obtained in Synthesis Example 39 and 1.4 g of acetyl chloride were added along with 50 mL of dichloroethane into a 100 mL 3-neck round-bottom flask in N₂ atmosphere and dissolved, cooled to 5° C., and then 1.8 g of triethyl amine was added thereto dropwise for 30 minutes, and the temperature was raised to room temperature and stirred for 2 hours. After washing 3 times with 100 mL of distilled water, distillation under reduced pressure, and then separated using a silica gel column to obtain 4.5 g of Compound 5-3.

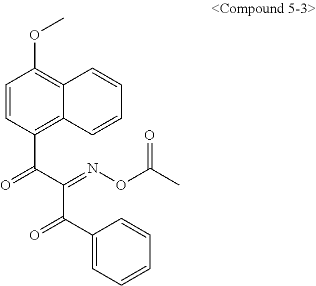 [SMILES: COc1ccc(C(=O)/C(=N/OC(C)=O)C(=O)c2ccccc2)c2ccccc12]

### Synthesis of Chromophore-Protecting Group Dye (Squarylium Dye)

### Synthesis Example 41 (Synthesis of Squaryllium Dye 1)

### Synthesis Example 41-1

100 g of 2,4,6-trimethyl-N-phenylaniline (473.3 mmol, Alchem Company), 86 g of 6-bromo-1-hexanol (475 mmol, TCI Company), 11.5 g of sodium hydride (479.2 mmol, Sigma Aldrich) and 500 g of N,N-dimethyl formamide were added into a 1,000 mL reactor equipped with a reflux apparatus, the temperature was raised to 80° C., and the mixture was stirred for 18 hours. After the reaction, the resultant was subjected to extraction using 500 mL of diethyl ether (Sigma Aldrich) and 1,000 mL of water, and the extract was distilled under reduced pressure and separated by column chromatography to obtain 130 g of an intermediate product such as Compound D-1 below.

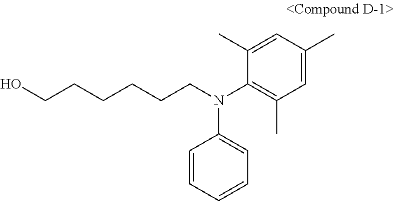 [SMILES: Cc1cc(C)c(N(CCCCCCO)c2ccccc2)c(C)c1]

### Synthesis Example 41-2

125 g (401.3 mmol) of Compound D-1, 23 g (201.6 mmol) of 3,4-dihydroxy-3-cyclobutene-1,2-dione (Sigma Aldrich) and 800 g of chlorobenzene (Sigma Aldrich) were added into a 2,000 mL reactor equipped with a reflux apparatus and a Dean-Stark apparatus, the temperature was raised to 120° C., and the mixture was stirred for 18 hours. After completion of the reaction, the solvent was distilled under reduced pressure and the resultant was separated by column chromatography to obtain 90 g of an intermediate product such as Compound D-2 below.

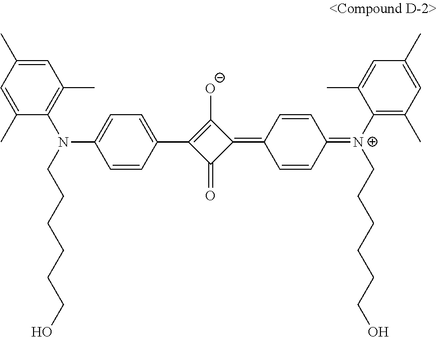 [SMILES: Cc1cc(C)c(N(CCCCCCO)c2ccc(C3=C([O-])C(=C4C=CC(=[N+](CCCCCCO)c5c(C)cc(C)cc5C)C=C4)C3=O)cc2)c(C)c1]

### Synthesis Example 41-3

70 g (99.9 mmol) of Compound D-2, 48 g (200.7 mmol) of Karenz BEI (Showa Denko Co.), and 400 g of chloroform (Sigma Aldrich) were added into a 1,000 mL reactor equipped with a reflux apparatus, the temperature was raised to 40° C., and the mixture was stirred for 18 hours to obtain an intermediate product such as Compound D-3. Then, after cooling the resultant to room temperature, 61 g (300.5 mmol) of isophthloyl chloride (Sigma Aldrich) and 41 g (301.1 mmol) of p-xylylenediamine (Sigma Aldrich) were added thereto dropwise for 3 hours and stirred for 18 hours. After completion of the reaction, the solvent was distilled under reduced pressure and the mixture was separated by column chromatography to obtain 80 g of squarylium dye 1 below.

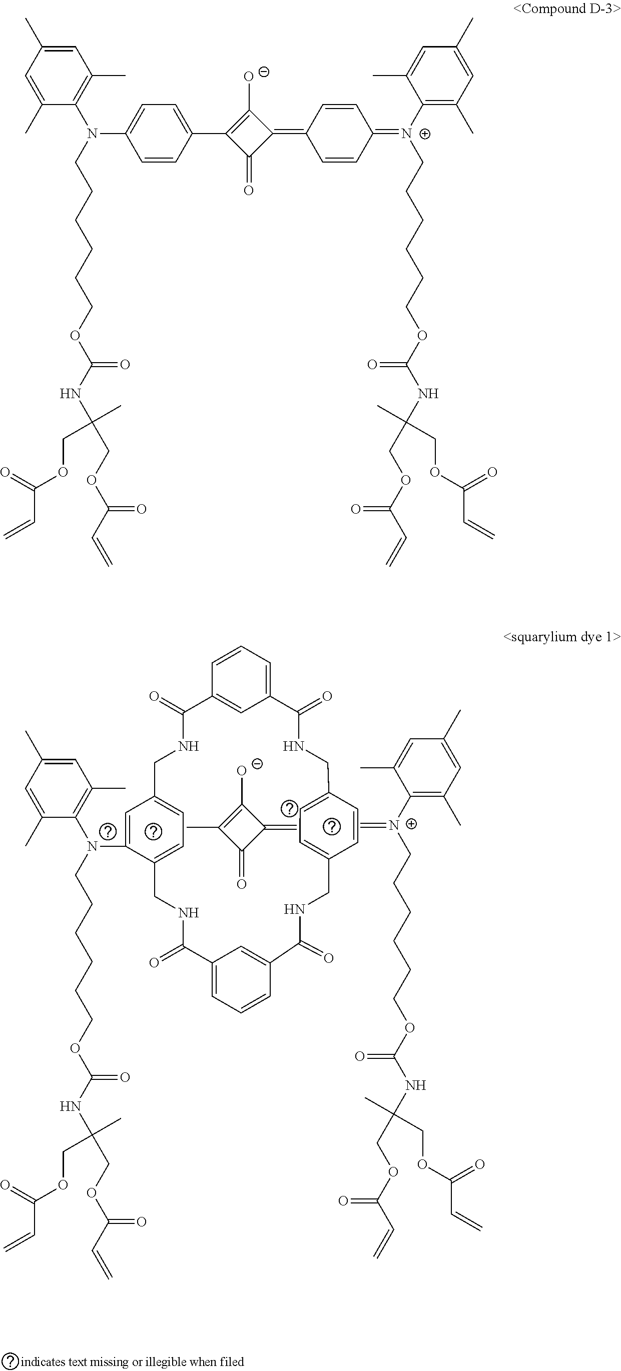

### Synthesis Example 42 (Synthesis of Squaryllium Dye 2)

### Synthesis Example 42-1

The synthesis was performed in the same manner as in Synthesis Example 41-1 except for adding 98 g (473.2 mmol,) of (4-(bromomethyl)cyclohexyl) methanol (Chemenu) instead of 86 g (475 mmol) of 6-bromo-1-hexanol (TCI). Through this, 135 g of an intermediate product such as Compound E-1 was obtained.

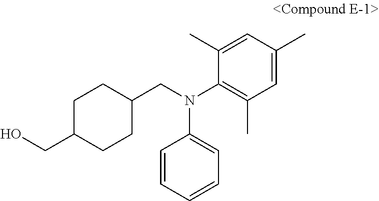 [SMILES: Cc1cc(C)c(N(CC2CCC(CO)CC2)c2ccccc2)c(C)c1]

### Synthesis Example 42-2

Synthesis was performed in the same manner as in Synthesis Example 41-2, except that 135 g (400 mmol) of Compound E-1 was used instead of 125 g (401.3 mmol) of Compound D-1 in Synthesis Example 41-2. Through this, it was possible to obtain 120 g of an intermediate such as Compound E-2.

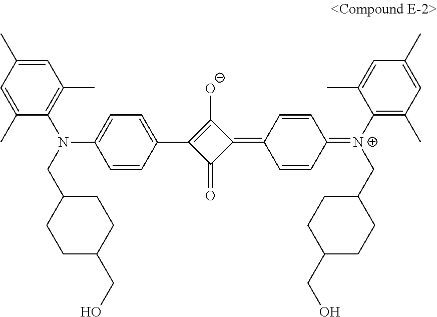 [SMILES: Cc1cc(C)c(N(CC2CCC(CO)CC2)c2ccc(C3=C([O-])C(=C4C=CC(=[N+](CC5CCC(CO)CC5)c5c(C)cc(C)cc5C)C=C4)C3=O)cc2)c(C)c1]

### Synthesis Example 42-3

Synthesis was performed in the same manner as in Synthesis Example 41-3, except for using 75 g (99.6 mmol) of Compound E-2 instead of 70 g (99.9 mmol) of Compound D-2 in Synthesis Example 41-3. Through this, it was possible to obtain 100 g of squarylium dye 2.

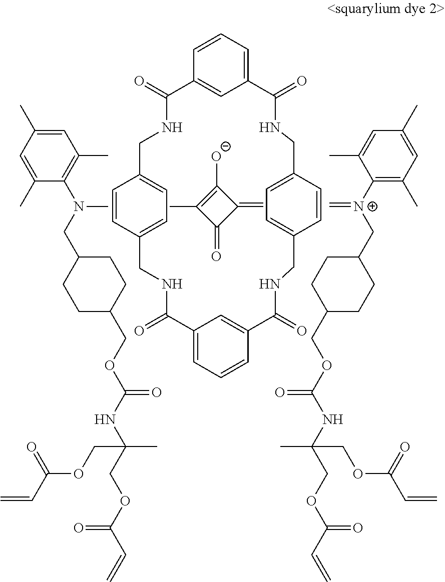

### Synthesis Example 43 (Synthesis of Squaryllium Dye 3)

### Synthesis Example 43-1

Synthesis was performed in the same manner as in Synthesis Example 41-1, except for using 95 g (472.5 mmol) of 4-(bromomethyl)benzyl alcohol (Apollo Scientific Co.) instead of 86 g (475 mmol) of 6-bromo-1-hexanol (TCI Co.) in Synthesis Example 41-1. Through this, it was possible to obtain 140 g of an intermediate product such as Compound F-1.

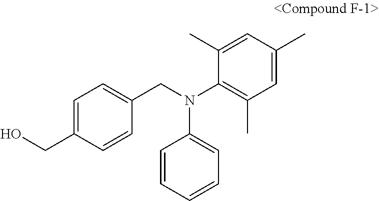 [SMILES: Cc1cc(C)c(N(Cc2ccc(CO)cc2)c2ccccc2)c(C)c1]

### Synthesis Example 43-2

Synthesis was performed in the same manner as in Synthesis Example 41-2 except for using 133 g (401.3 mmol) of Compound F-1 instead of 125 g (401.3 mmol) of Compound D-1 in Synthesis Example 41-2. Through this, it was possible to obtain 125 g of an intermediate product such as Compound F-2.

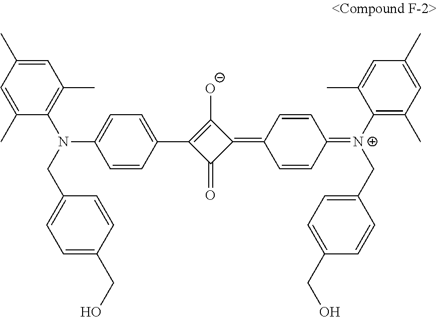 [SMILES: Cc1cc(C)c(N(Cc2ccc(CO)cc2)c2ccc(C3=C([O-])C(=C4C=CC(=[N+](Cc5ccc(CO)cc5)c5c(C)cc(C)cc5C)C=C4)C3=O)cc2)c(C)c1]

### Synthesis Example 43-3

Synthesis was performed in the same manner as in Synthesis Example 41-3 except for using 74 g (99.9 mmol) of Compound F-2 was used instead of 70 g (99.9 mmol) of Compound D-2 in Synthesis Example 41-3. Through this, it was possible to obtain 105 g of squarylium dye 3.

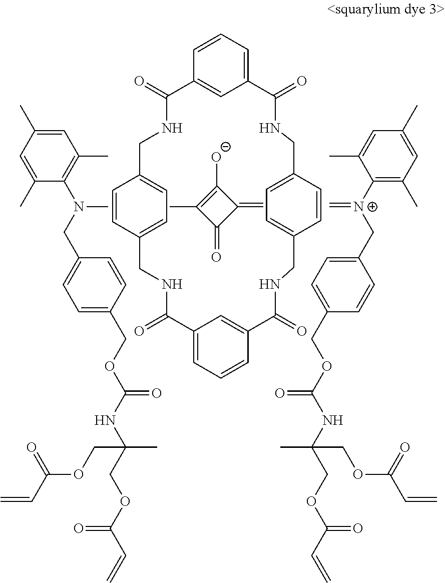

### Synthesis Example 44 (Synthesis of Squarylium Dye 4)

Synthesis was performed in the same manner as in Synthesis Example 41-3 except for using 61 g (299 mmol) of 2,6-pyridinedicarbonyl dichloride (Sigma Aldrich) instead of 61 g (300.5 mmol) of isophthaloyl chloride (Sigma Aldrich) in Synthesis Example 41-3. Through this, it was possible to obtain 110 g of squarylium dye 4.

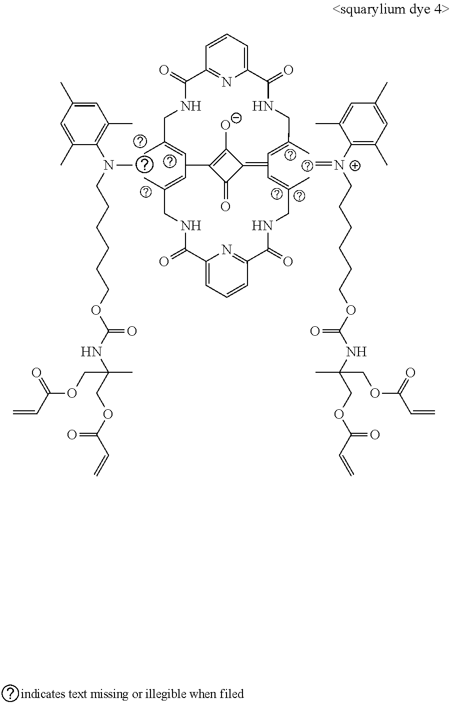

### Synthesis Example 45 (Synthesis of Squarylium Dye 5)

### Synthesis Example 45-1

Synthesis was performed in the same manner as in Synthesis Example 41-1 except for using 114 g (476.5 mmol) of Karenz BEI (Showa Denko Co.) instead of 86 g (475 mmol) of 6-bromo-1-hexanol (TCI Co.) in Synthesis Example 41-1. Through this, it was possible to obtain 190 g of an intermediate product such as Compound H-1.

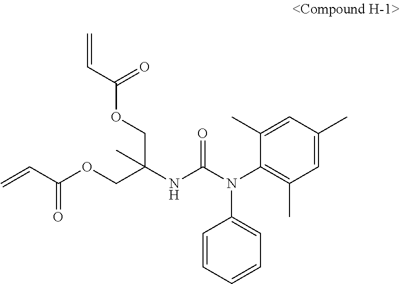 [SMILES: C=CC(=O)OCC(C)(COC(=O)C=C)NC(=O)N(c1ccccc1)c1c(C)cc(C)cc1C]

### Synthesis Example 45-2

Synthesis was performed in the same manner as in Synthesis Example 45-1 except for using 180 g (399.5 mmol) of Compound H-1 instead of 125 g (401.3 mmol) of Compound D-1 prepared in Synthesis Example 41-2. Through this, it was possible to obtain 170 g of an intermediate product such as Compound H-2.

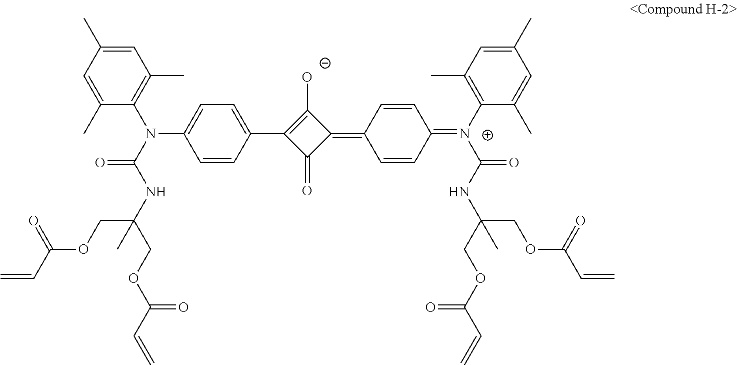

### Synthesis Example 45-3

97 g (99.1 mmol) of Compound H-2 and 300 g of chloroform (Sigma Aldrich) were added into a 1,000 mL reactor equipped with a reflux machine, and 61 g (300.5 mmol) of isophthaloyl chloride (Sigma Aldrich) and 41 g (301.1 mmol) of p-xylylenediamine (Sigma Aldrich) were added dropwise at room temperature for 3 hours, and the mixture was stirred for 18 hours. After completion of the reaction, the solvent was distilled under reduced pressure and the mixture was separated by column chromatography to obtain 75 g of squarylium dye 5 below.

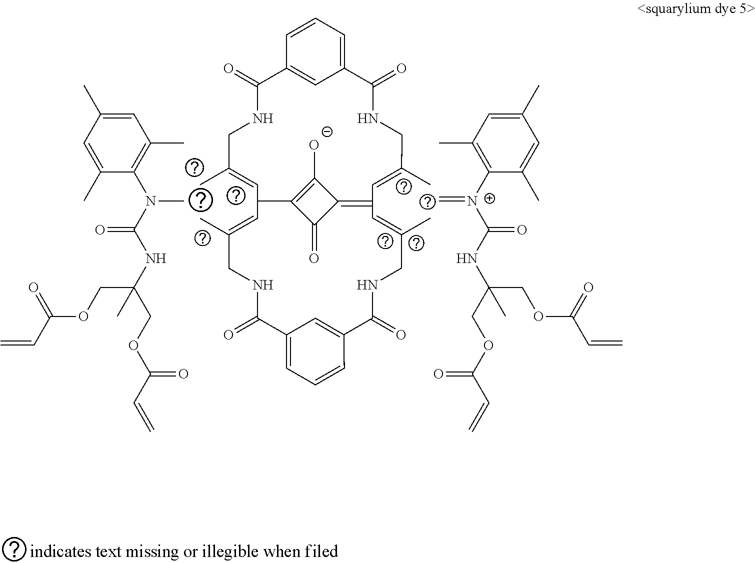

### Preparation Example

### (Preparation of Red Pigment Dispersion)

15 g of Irgaphor Red BT-CF (red pigment/BASF), 8.5 g of Disperbyk 163 (BYK), and 6.5 g of the polymer solution obtained in Synthesis Example 2, 70 g of propylene glycol methyl ether acetate, and 100 g of zirconia beads (diameter: 0.5 mm, Toray) were dispersed for 10 hours using a paint shaker (Asada) to obtain a dispersion.

### Experimental Example 1

### (Measurement of Molar Absorption Coefficient and Temperature of 5% Weight Loss of Photoinitiator Compound)

The maximum molar absorption coefficients of Compound 5-3 prepared in Synthesis Example 40, OXE-02 (BASF), and 1-hydroxycyclohexyl phenyl ketone were measured in the region of 320 nm to 380 nm using a UV-Vis spectrometer UV-2600 (Shimadzu) was measured, and the temperatures at which a 5% weight loss occurs in the three compounds were measured using TGA Q50 (TA), and the measured values are shown in Table 5.

TABLE 5

| | Temperature of | Maximum Molar Absorption |
|---|---|---|
| | 5% Weight Loss | Coefficient in Region of 320 |
| | (° C.) | nm to 380 nm (L/mol · cm) |
| Compound 5-3 | 188.53 | 16,000 (@332 nm) |
| OXE-02 (BASF) | 250.13 | 21,000 (@338 nm) |
| 1-Hydroxycyclohexyl | 143.12 | 2,400 (@330 nm) |
| phenyl ketone | | 14,000 (@245 nm) |

Referring to Table 5 above, in the case of OXE-02, the temperature at which the 5% weight loss occurred was 250° C. or higher, indicating a relatively higher numerical value compared to that of Compound 5-3, and the maximum molar absorption coefficient in the region of 320 nm to 380 nm was measured to be 21,000 (L/mol·cm) in the wavelength region of 338 nm.

Meanwhile, in the case of 1-hydroxycyclohexyl phenyl ketone, the maximum molar absorption coefficient in the region of 320 nm to 380 nm was very low as low as 2,400 (L/mol·cm) at 330 nm, and a rapid weight loss was shown at a temperature near 140° C.

In contrast, in the case of Compound 5-3 synthesized in Synthesis Example 40, the 5% weight loss occurred at 188.53° C., and the maximum molar absorption coefficient in the region of 320 nm to 380 nm was measured to be 16,000 (L/mol·cm) at 332 nm of wavelength.

### Examples 1 to 5

The photosensitive composition solutions were prepared according to the compositions shown in Table 6 below.

TABLE 6

| | | | | | | Comparative |
|---|---|---|---|---|---|---|
| | Example 1 | Example 2 | Example 3 | Example 4 | Example 5 | Example 1 |
| | (Composition | (Composition | (Composition | (Composition | (Composition | (Composition |
| | 1-1) | 1-2) | 1-3) | 1-4) | 1-5) | 1-6) |
| Squarylium dye 1 | 30 | — | — | — | — | — |
| Solution | | | | | | |
| Squarylium dye 2 | — | 30 | — | — | — | — |
| Solution | | | | | | |
| Squarylium dye 3 | — | — | 30 | — | — | — |
| Solution | | | | | | |
| Squarylium dye 4 | — | — | — | 30 | — | — |
| Solution | | | | | | |
| Squarylium dye 5 | — | — | — | — | 30 | — |
| Solution | | | | | | |
| Red Pigment | — | — | — | — | — | 30 |
| Dispersion of | | | | | | |
| Preparation | | | | | | |
| Example 1 | | | | | | |
| Compound 4-1 | 7 | 7 | 7 | 7 | 7 | 7 |
| Compound 5-3 | 0.5 | 0.5 | 0.5 | 0.5 | 0.5 | — |
| OXE-02 (BASF) | — | — | — | — | — | 0.5 |
| Polymer 1-1 | 7 | — | — | — | — | 7 |
| Polymer 1-2 | — | 7 | — | — | — | — |
| Polymer 2-1 | — | — | 7 | — | — | — |
| Polymer 3-1 | — | — | — | 7 | — | — |
| Polymer 4-1 | — | — | — | — | 7 | — |
| Propylene Glycol | 55.5 | 55.5 | 55.5 | 55.5 | 55.5 | 55.5 |
| Methyl Ether | | | | | | |
| Acetate (Daicel) | | | | | | |

The preparation method of the films using the composition solutions according to Table 6 is as follows (a photolithography step).

### (1) Step of Coating and Film Formation

Each of the compositions in Table 6 above was applied to a washed 10 cm*10 cm SiNx substrate to a thickness of 2.5 μm using a spin coater, and then heated at a temperature of 90° C. for 1 minute to remove the solvent to thereby form a coating film.

### (2) Step of Light Exposure

In order to form a pattern required for the obtained coating film, an open mask of a predetermined shape was interposed, and then irradiated with actinic rays of 190 nm to 500 nm. The light exposure machine used was MA-6, and the amount of light exposure was 50 mJ/cm².

### (3) Step of Development

Following the step of light exposure, the coating film was developed by dipping it into an aqueous solution of 0.04 wt % KOH at 25° C. for 1 minute, and then it was washed with water.

### (4) Step of Post-Treatment

The film obtained by the above development was subjected to post-baking treatment in an oven at 90° C. for 60 minutes, and then the films formed from the composition x in Table 6 were obtained.

### (5) Measurement of Outgas

After forming a coating film on a glass substrate through the steps (1), (2), (3), and (4) above, the photosensitive compositions of Examples 1 to 5 and Comparative Example 1 were cut to a size of 1 cm×3 cm and six samples 6 were prepared for each. Outgas was each collected at 250° C. for 30 minutes using JTD-505² of JAI. After measuring toluene assay samples (100 ppm, 500 ppm, and 1,000 ppm) using QP2020 GC/MS (Shimadzu), calibration curves were drawn up, and the amounts of outgas generated by the collected samples were measured.

The amounts of outgas generated of thus-obtained patterns and the maximum resolution (a minimum size pattern on the substrate) of the pattern formed on the substrate were measured, and the results are shown in Table 7 below.

TABLE 7

| | | | | | | Comparative |
|---|---|---|---|---|---|---|
| | Example 1 | Example 2 | Example 3 | Example 4 | Example 5 | Example 1 |
| Minimum Pattern | 5.2 | 5.4 | 4.0 | 4.2 | 4.3 | 13.1 |
| Size on Substrate | | | | | | |
| (μm) | | | | | | |
| Amount of Outgas | 3.3 | 3.2 | 3.6 | 3.5 | 3.7 | 4.7 |
| Generated (ppm) | | | | | | |

As shown in Table 7 above, it can be seen that there is a tendency that the amounts of outgas generation in Examples 1 and 2, in which Polymers 1-1 and 1-2 not containing a silane substituent were used as a binder resin, are lower than those in Examples 3 to 5, in which Polymers 2-1, 3-1, and 4-1 containing a silane substituent were used as a binder resin.

In addition, in the case of Examples 3 to 5, they showed a tendency in which the minimum size pattern on the substrate is smaller compared to Examples 1 and 2. It is determined that this is because when a binder resin substituted with a silane group is used, the adhesion to the substrate is improved, thereby improving the resolution of the final pattern after the PR process, but it also results in an increase of the amount of outgas generation.

Polymers 1-1 to 1-5 and Polymers 2-1 to 2-5 effectively form intermolecular bonds with surrounding compounds due to their structural characteristics thus making them more suitable for a photolithography process. Accordingly, it is determined that Examples 1 to 5 show higher resolution during the development process and have a lower amount of outgas generation compared to Comparative Example 1.

In Examples 1 to 5 of Table 6 Compound 5-3 was used as a photoinitiator, whereas in Comparative Example 1, OXE-02 (BASF) was used as a photoinitiator.

Upon comparison of the amount of outgas generation in Examples 1 to 5 and Comparative Example 1 through Table 7 above, it can be seen that the amount of outgas generation in Comparative Example 1 using OXE-02 (BASF), in which the temperature for a 5% weight loss is 200° C. or higher, was significantly increased compared to those of Examples 1 to 5.

In addition, upon comparison of the minimum pattern size on the substrates of Examples 1 to 5 and Comparative Example 1, the minimum pattern size on the substrate of Comparative Example 1 using OXE-02 (BASF), in which the temperature for a 5% weight loss is 200° C. or higher, was the largest compared to those of Examples 1 to 5.

According to Tables 5 and 7 above, it can be seen that Compound 5-3 in the present disclosure belongs to the conditions where the maximum molar absorption coefficient is 10,000 (L/mol·cm) or higher in the 320 nm to 380 nm region, and the temperature for a 5% weight loss is 200° C. or higher, and the minimum pattern size on the substrate is small and a lower amount of outgas is generated, which thus can significantly improve resolution, compared to photoinitiators that are not included in the above conditions.

### Examples 6 to 10; Comparative Example (Evaluation of Light Resistance and Chemical Resistance of Films)

The light resistance and chemical resistance of the composition films of Table 6 prepared through the photolithography step were evaluated in the following manner.

### Example 6

After evaluating the light resistance and chemical resistance of the films formed of the composition 1-1 by the following methods, the results are shown in Tables 8 and 9 below.

### 1. Light Resistance Evaluation (ΔEab* Measurement)

Eab* was measured by MCPD (Otsuka Co.) before and after the process of 100 hours in a Q-SUN XE-1 (Q-LAB Co.) light fastness tester of the film of composition 1-1 prepared by the photolithography step, respectively, and the amount of change is shown in Table 8 below.

2. Chemical Resistance Evaluation (Measurement of Change in Transmittance Before and After Immersion into Solvent)

After measuring the transmittance of the film of the composition 1-1 obtained through the photolithography step with UV-2600 (Shimadzu Co.), the film was placed in propylglen glycol methyl ether acetate at 50° C. for 5 minutes, and then the transmittance of the film was measured, and the chemical resistance was measured by observing the change in thickness. The transmittance, measured wavelength, and the measurement results are as shown in Table 9 below.

### Examples 7 to 10; Comparative Example 2

In Example 6, films were formed in the same manner as in Example 1 using Compositions 1-2 to 1-6 instead of Composition 1-1. The light resistance and chemical resistance of the formed films were evaluated in the same manner as in Example 1, and the results are shown in Tables 8 and 9.

TABLE 8

| | | | | | | Comparative |
|---|---|---|---|---|---|---|
| | Example 6 | Example 7 | Example 8 | Example 9 | Example 10 | Example 2 |
| Film | Composition | Composition | Composition | Composition | Composition | Composition |
| Composition | 1-1 | 1-2 | 1-3 | 1-4 | 1-5 | 1-6 |
| Change in | 3.05 | 2.97 | 2.94 | 2.99 | 2.78 | 11.24 |
| Optical | | | | | | |
| Properties | | | | | | |
| Before and After | | | | | | |
| Light Resistance | | | | | | |
| Test (ΔEab*) | | | | | | |

TABLE 9

| | | | | | Transmittance by | | | Difference in | | |
|---|---|---|---|---|---|---|---|---|---|---|
| | | | | | Wavelength After | | | Transmittance by | | |
| | | Transmittance by | | | Immersion in Solvent (%) | | | Wavelength Before and | | |
| | Film | Wavelength Before | | | (propylene glycol methyl | | | After Immersion in | | |
| | Composition | Immersion in Solvent (%) | | | ether acetate, 50° C., 5 min) | | | Solvent (%) | | |
| Wavelength | — | 450 | 530 | 620 | 450 | 530 | 620 | 450 | 530 | 620 |
| (nm) | | | | | | | | | | |
| Example 6 | Composition | 0.09 | 81.1 | 0.07 | 0.18 | 83.2 | 0.21 | 0.09 | 2.1 | 0.14 |
| | 1-1 | | | | | | | | | |
| Example 7 | Composition | 0.07 | 81.1 | 0.04 | 0.18 | 82.4 | 0.25 | 0.11 | 1.3 | 0.21 |
| | 1-2 | | | | | | | | | |
| Example 8 | Composition | 0.07 | 80.9 | 0.04 | 0.18 | 82.6 | 0.13 | 0.11 | 1.7 | 0.09 |
| | 1-3 | | | | | | | | | |
| Example 9 | Composition | 0.07 | 80.2 | 0.04 | 0.12 | 81.9 | 0.14 | 0.05 | 1.7 | 0.1 |
| | 1-4 | | | | | | | | | |
| Example 10 | Composition | 0.06 | 80.7 | 0.04 | 0.14 | 81.7 | 0.16 | 0.08 | 1 | 0.12 |
| | 1-5 | | | | | | | | | |
| Comparative | Composition | 0.41 | 72.1 | 0.75 | 0.67 | 72.61 | 0.9 | 0.26 | 0.51 | 0.15 |
| Example 2 | 1-6 | | | | | | | | | |

It can be seen from Table 8 that the films of Example 6 to Example 10, which include the chromophore-protecting group dye of the present disclosure and the alkali-soluble resin of the present disclosure, showed an improvement in light resistance compared to the film Comparative Example 2, which includes the alkali-soluble resin of the present disclosure but does not include the chromophore-protecting group dye of the present disclosure.

It can be seen from Table 9 that the films of Example 6 to Example 10, which include the chromophore-protecting group dye of the present disclosure, the difference in transmittance was decreased compared to the film of Comparative Example 2, which does not include the chromophore-protecting group dye of the present disclosure, and accordingly, it can be seen that the films of Example 6 to Example 10, which include the chromophore-protecting dye of the present disclosure, showed an improvement in chemical resistance.

The above description is merely illustrative of the present disclosure, and those skilled in the art will be able to make various modifications without departing from the essential characteristics of the present disclosure.

Accordingly, the embodiments disclosed herein are illustrative and not intended to limit the invention, and the spirit and scope of the present disclosure are not limited by these embodiments. The protection scope of the present disclosure should be construed according to the claims, and all techniques within the equivalent range should be construed as being included in the scope of the present disclosure.

### CODE EXPLANATION

1: substrate
2: TFT
3: TFT layer
4: first electrode
5: pixel separation unit
6: organic material layer
7: second electrode
8: scaling layer
9: touch screen panel (TSP)
10: color unit
11: color separation unit
12: flattening layer

What is claimed is:

1. A photosensitive resin composition comprising an alkali-soluble resin; a reactive unsaturated compound; a photoinitiator having a maximum molar absorption coefficient of 10,000 (L/mol·cm) or more in the region of 320 nm to 380 nm and a loss of 5 wt % at 200° C. or less; a reactive dye comprising a chromophore of Formula (4) below and a protecting group of Formula (5) below; and a solvent: 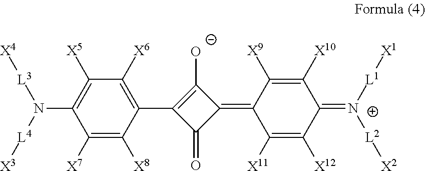
wherein in Formula 4 above,
1) L¹ to L⁴ are each independently a single bond; a fluorenylene group; C₁₋₃₀ alkylene; a C₃₋₃₀ cycloalkylene group; a C₁₋₃₀ alkoxylene group, a C₂₋₃₀ polyethyleneoxy group; a C₆₋₃₀ arylene group; a C₂₋₃₀ heterocyclic ring; or a combination thereof,
2) X¹ to X⁴ are each independently hydrogen; deuterium; a fluorenyl group; a C₆₋₃₀ aryl group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁₋₃₀ alkyl group; a C₂₋₃₀ alkenyl group; a C₂₋₃₀ alkynyl group; a C₁₋₃₀ alkoxy group; a C₆₋₃₀ aryloxy group; a C₃₋₃₀ cycloalkyl group; Formula (4-A) or a combination thereof,
3) at least one of X¹ to X⁴ is Formula (4-A), 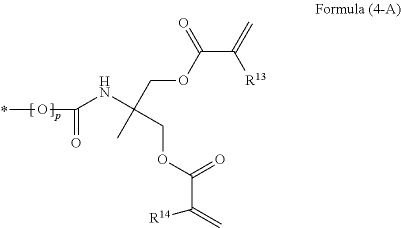
wherein in Formula (4-A) above,
3-1) * is a moiety bonded to L¹ to L⁴ or N,
3-2) p is an integer from 0 to 1,
3-3) when Formula (4-A) is directly bonded to N, p is 0,
3-4) R¹³ and R¹⁴ are independently hydrogen or a methyl group,
4) X⁵ to X¹² are each independently hydrogen; deuterium; halogen; a fluorenyl group; a C₆₋₃₀ aryl group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁₋₃₀ alkyl group; a C₂₋₃₀ alkenyl group; a C₂₋₃₀ alkynyl group; a C₁₋₃₀ alkoxy group; a C₆₋₃₀ aryloxy group; a C₃₋₃₀ cycloalkyl group; or a C₁₋₃₀ alkylamine group,
5) X⁵ to X¹² may bind to each other to form a ring, 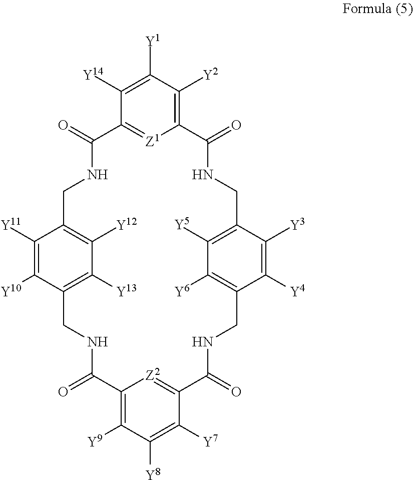
wherein in Formula (5) above,
6) Z¹ and Z² are each independently a carbon atom or a nitrogen atom,
7) Y¹ to Y¹⁴ are each independently hydrogen; deuterium; halogen; a fluorenyl group; a C₆₋₃₀ aryl group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁₋₃₀ alkyl group; a C₂₋₃₀ alkenyl group; a C₂₋₃₀ alkynyl group; a C₁₋₃₀ alkoxy group; a C₆₋₃₀ aryloxy group; a C₃₋₃₀ cycloalkyl group; or a C₁₋₃₀ alkylamine group,
8) Y¹ to Y¹⁴ may bind to each other to form a ring, and
9) the X¹ to X¹⁴, Y¹ to Y¹⁴, and L¹ to L⁴ may each be further substituted with one or more substituents selected from the group consisting of deuterium; halogen; a silane group substituted or unsubstituted with a C₁₋₃₀ alkyl group or C₆₋₃₀ aryl group; a siloxane group; a boron group; a germanium group; a cyano group; an amino group; a nitro group; a C₁₋₃₀ alkylthio group; a C₁₋₃₀ alkoxy group; a C₆₋₃₀ arylalkoxy group; a C₁₋₃₀ alkyl group; a C₂₋₃₀ alkenyl group; a C₂₋₃₀ alkynyl group; a C₆₋₃₀ aryl group; a C₆₋₃₀ aryl group substituted with deuterium; a fluorenyl group; a C₂₋₃₀ heterocyclic group comprising at least one heteroatom among O, N, S, Si, and P; a C₃₋₃₀ alicyclic group; a C₇₋₃₀ arylalkyl group; a C₈₋₃₀ arylalkenyl group; and a combination thereof; or may form a ring between the neighboring substituents.

2. The photosensitive resin composition of claim 1, wherein in Formula (4) above, at least one of X¹ and X² is Formula (4-A), and at least one of X³ and X⁴ is Formula (4-A).

3. The photosensitive resin composition of claim 2, wherein among the X¹ to X⁴ in Formula (4) above, the remainders where Formula (4-A) is not substituted are each independently a C₆₋₃₀ aryl group; a C₁₋₃₀ alkyl group; a C₃₋₃₀ cycloalkyl group; or a combination thereof.

4. The photosensitive resin composition of claim 1, wherein the chromophore comprising the structure represented by Formula (4) above has a maximum absorption peak at a wavelength of 520 nm to 680 nm.

5. The photosensitive resin composition of claim 1, wherein the cage width of the protecting group comprising the structure represented by Formula (5) above is 6.5 Å to 7.5 Å, and the volume of the protecting group is 10 Å to 16 Å.

6. The photosensitive resin composition of claim 1, which comprises a chromophore comprising a structure represented by Formula (4) above and a protecting group comprising a structure represented by Formula (5) in a 1:1 molar ratio.

7. The photosensitive resin composition of claim 1, wherein the dye is comprised in an amount of 0.1 wt % to 50 wt % based on the solid content excluding the solvent.

8. The photosensitive resin composition of claim 1, wherein the alkali-soluble resin comprises a repeating unit of Formula (1) below: 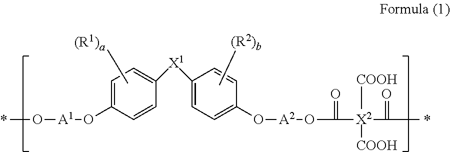
wherein in Formula (1) above,
1) * indicates a moiety where a bond is connected as a repeating unit,
2) R¹ and R² are each independently hydrogen; deuterium; halogen; a C₆₋₃₀ aryl group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁₋₃₀₂₀ alkyl group; a C₂₋₃₀₂₀ alkenyl group; a C₂₋₃₀₂₀ alkynyl group; a C₁₋₃₀₂₀ alkoxy group; a C₆₋₃₀ aryloxy group; a fluorenyl group; a carbonyl group; an ether group; or a C₁₋₃₀₂₀ alkoxycarbonyl group,
3) R¹ and R² may each form a ring with neighboring groups,
4) a and b are each independently an integer from 0 to 4,
5) X¹ is a single bond, O, CO, SO₂, CR′R″, SiR′R″, Formula (A), or Formula (B),
6) X² is a C₆₋₃₀ aryl group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁₋₃₀₂₀ alkyl group; a C₂₋₃₀₂₀ alkenyl group; a C₂₋₃₀₂₀ alkynyl group; a C₁₋₃₀₂₀ alkoxy group; a C₆₋₃₀ aryloxy group; or a combination thereof,
7) R′ and R″ are each independently hydrogen; deuterium; halogen; a C₆₋₃₀ aryl group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁₋₃₀₂₀ alkyl group; a C₂₋₃₀₂₀ alkenyl group; a C₂₋₃₀₂₀ alkynyl group; a C₁₋₃₀₂₀ alkoxy group; a C₆₋₃₀ aryloxy group; a fluorenyl group; a carbonyl group; an ether group; or a C₁₋₃₀₂₀ alkoxycarbonyl group,
8) R′ and R″ may each form a ring with neighboring groups,
9) A¹ and A² are each independently Formula (C) or Formula (D),
10) the ratio of Formula (C) to Formula (D) in the polymer chain of the resin comprising the repeating unit represented by Formula (1) meets 1:9 to 9:1, 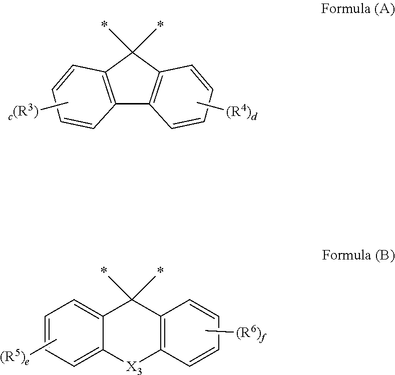
wherein in Formula (A) and Formula (B) above,
11-1) * indicates a binding position,
11-2) X³ is O, S, SO₂, or NR′,
11-3) R′ is hydrogen; deuterium; halogen; a C₆₋₃₀ aryl group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁₋₃₀₂₀ alkyl group; a C₂₋₃₀₂₀ alkenyl group; a C₂₋₃₀₂₀ alkynyl group; a C₁₋₃₀₂₀ alkoxy group; a C₆₋₃₀ aryloxy group; a fluorenyl group; a carbonyl group; an ether group; or a C₁₋₃₀₂₀ alkoxycarbonyl group,
11-4) R³ to R⁶ are each independently hydrogen; deuterium; halogen; a C₆₋₃₀ aryl group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁₋₃₀₂₀ alkyl group; a C₂₋₃₀₂₀ alkenyl group; a C₂₋₃₀₂₀ alkynyl group; a C₁₋₃₀₂₀ alkoxy group; a C₆₋₃₀ aryloxy group; a fluorenyl group; a carbonyl group; an ether group; or a C₁₋₃₀₂₀ alkoxycarbonyl group,
11-5) R³ to R⁶ may each form a ring with neighboring groups, and
11-6) c to f are each independently an integer from 0 to 4, 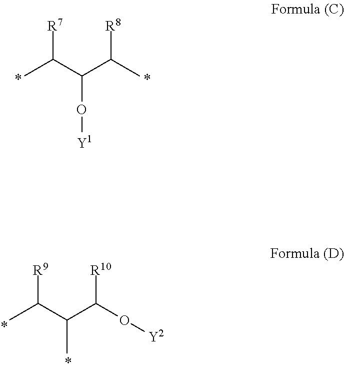
wherein in Formula (C) and Formula (D) above,
12-1) * indicates a binding position,
12-2) R⁷ to R¹⁰ are each independently hydrogen; deuterium; halogen; a C₆₋₃₀ aryl group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁₋₃₀₂₀ alkyl group; a C₂₋₃₀₂₀ alkenyl group; a C₂₋₃₀₂₀ alkynyl group; a C₁₋₃₀₂₀ alkoxy group; a C₆₋₃₀ aryloxy group; a fluorenyl group; a carbonyl group; an ether group; or a C₁₋₃₀₂₀ alkoxycarbonyl group, and
12-3) Y¹ and Y² are each independently Formula (E) or Formula (F), 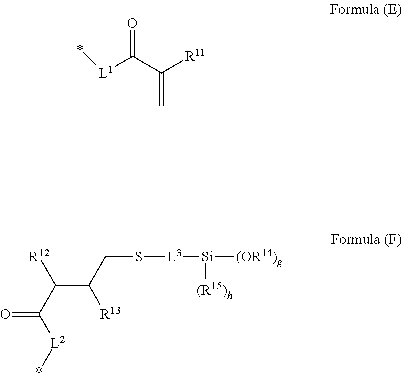
wherein in Formula (E) and Formula (F) above,
13-1) * is indicates a binding position,
13-2) R¹¹ to R¹⁵ are each independently hydrogen; deuterium; halogen; a C₆₋₃₀ aryl group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁₋₃₀₂₀ alkyl group; a C_{2-30/20} alkenyl group; a C₂₋₃₀₂₀ alkynyl group; a C₁₋₃₀₂₀ alkoxy group; a C₆₋₃₀ aryloxy group; a fluorenyl group; a carbonyl group; an ether group; or a C₁₋₃₀₂₀ alkoxycarbonyl group,
13-3) L¹ to L³ are each independently a single bond, C₁₋₃₀ alkylene, C₆₋₃₀ arylene, or a C₂₋₃₀ heterocyclic ring, and
13-4) g and h are each independently an integer from 0 to 3; with the proviso that the sum of g+h=3,
14) the R¹ to R¹⁵, R′, R″, X¹, X², and L¹ to L³ and the ring formed between the neighboring substituents may each be further substituted with one or more substituents selected from the group consisting of deuterium; halogen; a silane group substituted or unsubstituted with a C₁₋₃₀ alkyl group or C₆₋₃₀ aryl group; a siloxane group; a boron group; a germanium group; a cyano group; an amino group; a nitro group; a C₁₋₃₀ alkylthio group; a C₁₋₃₀ alkoxy group; a C₆₋₃₀ arylalkoxy group; a C₁₋₃₀ alkyl group; a C₂₋₃₀ alkenyl group; a C₂₋₃₀ alkynyl group; a C₆₋₃₀ aryl group; a C₆₋₃₀ aryl group substituted with deuterium; a fluorenyl group; a C₂₋₃₀ heterocyclic group comprising at least one heteroatom among O, N, S, Si, and P; a C₃₋₃₀ alicyclic group; a C₇₋₃₀ arylalkyl group; a C₈₋₃₀ arylalkenyl group; and a combination thereof; or may form a ring between the neighboring substituents.

9. The photosensitive resin composition of claim 1, wherein the alkali-soluble resin has a weight average molecular weight of 1,000 g/mol to 100,000 g/mol.

10. The photosensitive resin composition of claim 8, wherein the ratio of Formula (E) to Formula (F) in the polymer chain of the resin comprising the repeating unit represented by Formula (1) above is 2:0 to 1:1.

11. The photosensitive resin composition of claim 1, wherein the resin comprising the repeating unit represented by Formula (1) above is comprised in an amount of 1 wt % to 50 wt % based on the total amount of the photosensitive resin composition.

12. The photosensitive resin composition of claim 1, wherein the reactive unsaturated compound is comprised in an amount of 1 wt % to 40 wt % based on the total amount of the photosensitive resin composition.

13. The photosensitive resin composition of claim 1, wherein the reactive unsaturated compound comprises the compound represented by Formula (2) below: 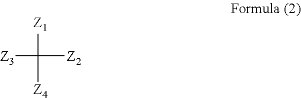
wherein in Formula (2) above, two or more among Z₁ to Z₄ independently have the structure of Formula (G) below; the remainder among Z₁ to Z₄ are each independently hydrogen; deuterium; halogen; a methyl group; an ethyl group; a methyl hydroxy group; a C₆₋₃₀ aryl group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁₋₃₀ alkyl group; a C₂₋₃₀ alkenyl group; a C₂₋₃₀ alkynyl group; a C₁₋₃₀ alkoxy group; a C₆₋₃₀ aryloxy group; a fluorenyl group; a carbonyl group; an ether group; or a C₁₋₃₀ alkoxycarbonyl group, 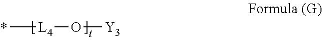
wherein in Formula (G) above,
1) t is an integer of 1 to 20,
2) L₄ is a single bond, C₁₋₃₀ alkylene, C₆₋₃₀ arylene, or a C₂₋₃₀ heterocyclic ring,
3) Y₃ is Formula (H) or Formula (I) below, 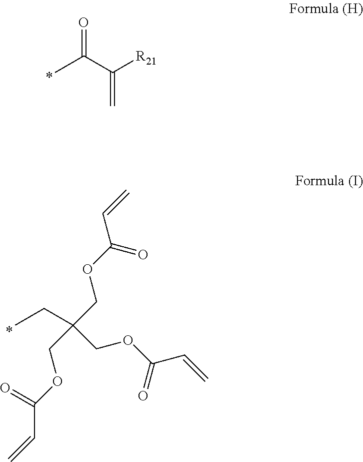
wherein in Formula (H) above, R₂₁ is hydrogen; deuterium; halogen; a methyl group;
an ethyl group; a methyl hydroxy group; a C₆₋₃₀ aryl group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁₋₃₀ alkyl group; a C₂₋₃₀ alkenyl group; a C₂₋₃₀ alkynyl group; a C₁₋₃₀ alkoxy group; a C₆₋₃₀ aryloxy group; a fluorenyl group; a carbonyl group; an ether group; or a C₁₋₃₀ alkoxycarbonyl group.

14. The photosensitive resin composition of claim 1, wherein the photoinitiator is comprised in an amount of 0.01 wt % to 10 wt % based on the total amount of the photosensitive resin composition.

15. The photosensitive resin composition of claim 1, wherein the photoinitiator comprises the compound represented by Formula (3) below: 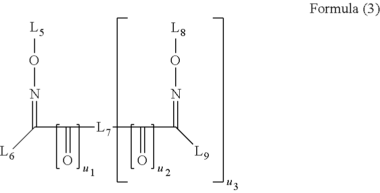
wherein in Formula (3) above,
1) u₁ to u₃ are each independently an integer of 0 or 1,
2) L₅ and L₈ are Formula (J) below,
3) L₆, L₇, and L₉ are each independently a C₆₋₃₀ aryl group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₃₋₃₀ alicyclic group; a C₁₋₃₀ alkyl group; a C₂₋₃₀ alkenyl group; a C₂₋₃₀ alkynyl group; a C₁₋₃₀ alkoxy group; a C₆₋₃₀ aryloxy group; a fluorenyl group; a carbonyl group; an ether group; C₁₋₃₀ alkoxycarbonyl; C₁₋₃₀ alkylene; C₆₋₃₀ arylene group; Formula (K); Formula (L); Formula (M); Formula (N); or a combination thereof, 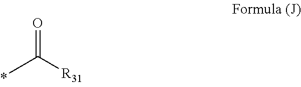
wherein in Formula (J) above,
1) * is indicates a binding position,
2) R₃₁ is hydrogen; deuterium; halogen; a methyl group; an ethyl group; a methyl hydroxy group; a C₆₋₃₀ aryl group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁₋₃₀ alkyl group; a C₂₋₃₀ alkenyl group; a C₂₋₃₀ alkynyl group; a C₁₋₃₀ alkoxy group; a C₆₋₃₀ aryloxy group; a fluorenyl group; a carbonyl group; an ether group; or a C₁₋₃₀ alkoxycarbonyl group, 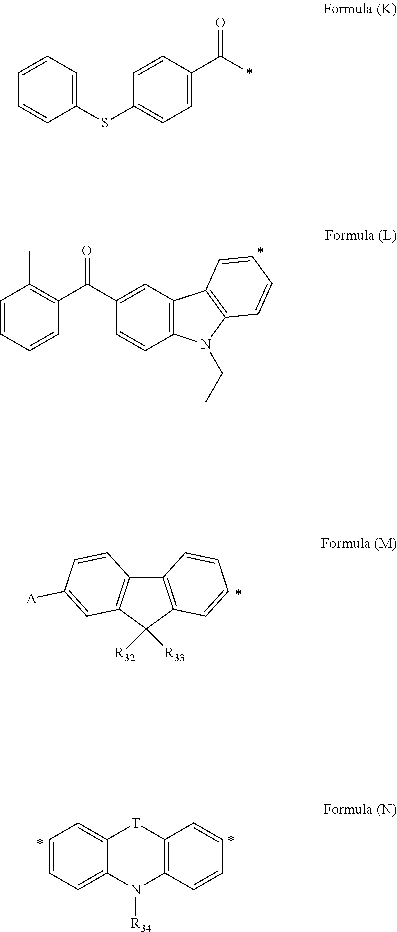
wherein in Formula (M) and Formula (N) above,
1) * is indicates a binding position,
2) A is hydrogen; O; S; a silane group; a siloxane group; a boron group; a germanium group; a cyano group; a nitro group; a nitrile group; an amino group substituted or unsubstituted with a C₁₋₃₀ alkyl group, a C₆₋₃₀ aryl group, or a C₂₋₃₀ heterocyclic group; a C₁₋₃₀ alkylthio group; a C₁₋₃₀ alkyl group; a C₁₋₃₀ alkoxy group; a C₆₋₃₀ arylalkoxy group; a C₂₋₃₀ alkenyl group; a C₂₋₃₀ alkynyl group; a C₆₋₃₀ aryl group; a C₆₋₃₀ aryl group substituted with deuterium; a fluorenyl group; a C₂₋₃₀ heterocyclic group including at least one heteroatom among O, N, S, Si, and P; a C₃₋₃₀ alicyclic group; a C₇₋₃₀ arylalkyl group; a C₈₋₃₀ arylalkenyl group; and a combination thereof,
3) R₃₂ to R₃₄ are each independently hydrogen; deuterium; halogen; a C₆₋₃₀ aryl group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁₋₃₀ alkyl group; a C₂₋₃₀ alkenyl group; a C₂₋₃₀ alkynyl group; a C₁₋₃₀ alkoxy group; a C₆₋₃₀ aryloxy group; a fluorenyl group; a carbonyl group; an ether group; or a C₁₋₃₀ alkoxycarbonyl group, and
4) T is S, O, or Se.

16. A pattern or film formed from the photosensitive resin composition according to claim 1.

17. The pattern or film of claim 16, wherein the difference in transmittance at 450 nm to 620 nm before and after being immersed in propylene glycol methyl ether acetate at 50° C. for 5 minutes is 0.01% to 2.5%.

18. An organic light emitting display device comprising the pattern or film according to claim 17.

19. An electronic device comprising the display device of claim 18 and a control unit for operating the display device.
